(19) United States
(12) Patent Application Publication
(10) Pub. No.: US 2025/0068025 A1
(43) Pub. Date: Feb. 27, 2025

(54) LIGHT CONTROLLING PANEL AND TRANSPARENT DISPLAY DEVICE INCLUDING THE SAME

(71) Applicant: LG Display Co., Ltd., Seoul (KR)

(72) Inventors: KyoungSang YOON, Paju-si (KR); Youngki SONG, Paju-si (KR)

(73) Assignee: LG Display Co., Ltd., Seoul (KR)

(21) Appl. No.: 18/804,521

(22) Filed: Aug. 14, 2024

(30) Foreign Application Priority Data
Aug. 24, 2023 (KR) 10-2023-0111484

(51) Int. Cl. G02F 1/167; G02F 1/1676

(52) U.S. Cl. CPC G02F 1/167; G02F 1/1676

(57) ABSTRACT

A light controlling panel can include: a first electrode and a second electrode disposed to face each other; and a dielectric layer disposed between the first electrode and the second electrode. The dielectric layer can include: a first dielectric including a first dielectric material and a groove, the first dielectric material having a first dielectric permittivity; and a second dielectric including a plurality of light blocking particles and a solvent including a second dielectric material having a second dielectric permittivity less than the first dielectric permittivity.

### CROSS-REFERENCE TO RELATED APPLICATIONS

This application claims the benefit of and priority to Korean Patent Application No. 10-2023-0111484, filed in the Republic of Korea on Aug. 24, 2023, the entire contents of which are incorporated herein by reference for all purposes.

### BACKGROUND

### 1. Technical Field

The present disclosure relates to a light controlling panel and a transparent display device including the light controlling panel.

### 2. Discussion of the Related Art

Research on transparent display devices, which allow users to see objects or images located on rear surface of the display device, has been actively conducted recently. A transparent display device includes a display area where images are displayed. The display area includes a transmissive area capable of transmitting external light and a non-transmissive area. Through the transmissive area, a high light transmittance can be achieved in the display area. Unlike conventional display devices, these transparent display devices have transmissive area, prompting research to maintain a certain level of contrast ratio even in dark or illuminated environments by considering the transmissive area.

The description of the related art should not be assumed to be prior art merely because it is mentioned in or associated with this section. The description of the related art includes information that describes one or more aspects of the subject technology, and the description in this section does not limit the invention.

### SUMMARY

In one or more aspects, the present disclosure is directed to providing a light controlling panel and a transparent display device including the light controlling panel capable of implementing a light-blocking mode that blocks light and a light-transmitting mode that transmits light.

An aspect of the present disclosure is directed to a light controlling panel and a transparent display device including the light controlling panel capable of improving a light transmittance in the light-transmitting mode.

Another aspect of the present disclosure is directed to providing a light controlling panel and a transparent display device including the light controlling panel capable of improving on ESG (Environment/Social/Governance) qualities by reducing the generation of greenhouse gases due to the manufacturing process for producing a display device.

Additional advantages and features of the disclosure will be set forth in part in the description which follows and in part will become apparent to those having ordinary skill in the art upon examination of the following or can be learned from practice of the disclosure. Other benefits of the disclosure can be realized and attained by the structure particularly pointed out in the written description and claims hereof as well as the appended drawings.

To achieve these and other advantages and aspects of the disclosure, as embodied and broadly described herein, in one or more aspects, there is provided a light controlling panel including a first electrode and a second electrode disposed to face each other and a dielectric layer disposed between the first electrode and the second electrode, wherein the dielectric layer includes a first dielectric including a first dielectric material and a groove, the first dielectric material having a first dielectric permittivity and a second dielectric including a plurality of light blocking particles and a solvent including a second dielectric material having a second dielectric permittivity less than the first dielectric permittivity.

In one or more aspects of the present disclosure, there is a transparent display device including a display panel including a transmissive area for transmitting an external light and a non-transmissive area on which a plurality of pixels are disposed, a light controlling panel including a first electrode, a second electrode, and a dielectric layer disposed between the first electrode and the second electrode, the dielectric layer includes a first dielectric including a first dielectric material, a guide pattern having a curved top surface, and a groove disposed on at least one side of the guide pattern, and a second dielectric including a plurality of light blocking particles and a second dielectric material.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure. In the drawings:

FIG. 1 is a perspective view illustrating a transparent display device according to one or more example embodiments of the present disclosure;

FIG. 2 is a plan view illustrating a transparent display panel according to one or more example embodiments of the present disclosure;

FIG. 3 is a diagram illustrating an example of a transmissive area and a non-transmissive area provided in the display area of FIG. 2;

FIG. 4 is a cross-sectional view illustrating an example of I-I′ of FIG. 3;

FIG. 5 is a perspective view illustrating a light controlling panel according to one or more example embodiments of the present disclosure;

FIG. 6 is a cross-sectional view illustrating an example of one side of FIG. 5 in a light-blocking mode;

FIG. 7 is a cross-sectional view illustrating an example of an arrangement relationship between components of a transparent display panel and components of the light controlling panel;

FIG. 8 is a cross-sectional view illustrating an example of one side of FIG. 5 in a light-transmitting mode;

FIG. 9 is a plan view illustrating an example of a spacer, a guide pattern, and a groove;

FIG. 10 is a cross-sectional view illustrating another example of one side of FIG. 5 in a light-blocking mode;

FIG. 11 is a cross-sectional view illustrating another example of one side of FIG. 5 in a light-transmitting mode;

FIG. 12 is a plan view illustrating another example of a spacer, a guide pattern, and a groove;

FIG. 13 is a plan view illustrating another example of a spacer, a guide pattern, and a groove;

FIG. 14 is a diagram illustrating the difference in electric field direction depending on the shape of the guide pattern of the first dielectric; and

FIG. 15 is a diagram illustrating the difference in electric field direction according to the difference between a dielectric permittivity of the first dielectric and a dielectric permittivity of the second dielectric.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art. Furthermore, the present disclosure is only defined by scopes of claims.

A shape, a size, a ratio, an angle, and a number, and the like disclosed in the drawings for describing embodiments of the present disclosure are merely an example, and thus the present disclosure is not limited to the illustrated details. Like reference numerals refer to like elements throughout. In the following description, when the detailed description of the relevant known technology is determined to unnecessarily obscure the aspects of the present disclosure, the detailed description will be omitted. In a case where “comprise,” “have,” and “include”, “contain,” “constitute,” “make up of,” “formed of,” and the like described in the present disclosure are used, another part can be added unless “only” is used. The terms of a singular form can include plural forms unless referred to the contrary.

In construing an element, the element is construed as including an error range although there is no explicit description. Any implementation described herein as an “example” is not necessarily to be construed as preferred or advantageous over other implementations.

In describing a temporal relationship, for example, when a temporal precedence relationship is described such as “after”, “following”, “next”, “before”, etc., it can include cases that are not consecutive unless “immediately” or “directly” are used, that is, one or more other parts may be disposed located between the two parts. For example, where an element or layer is disposed “on” another element or layer, a third layer or element may be interposed therebetween.

In describing a positional relationship, for example, when a position relation between two parts is described as “on”, “over”, “under”, and “next”, one or more other parts can be disposed between the two parts unless “just” or “direct” is used.

It will be understood that, although the terms “first,” “second,”, “A” “B” “(A)” or “(B)” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure can be partially or totally coupled to or combined with each other, and can be variously inter-operated and driven technically. The embodiments of the present disclosure can be carried out independently from each other or can be carried out together with a co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

The features of the various embodiments of the present disclosure may be partially or entirely combined with each other, and may be technically associated with each other or operate with each other. The embodiments may be implemented independently of each other and may be implemented together in an association relationship.

Hereinafter, with reference to the accompanying drawings, one example of a display device according to the present disclosure is described. In assigning reference numerals to the components in each drawing, the same component can have the same numeral as far as possible, even if it is shown in different drawings. In addition, when the detailed description of the relevant known technology is determined to unnecessarily obscure the important point of the present disclosure, the detailed description will be omitted.

Hereinafter, with reference to the accompanying drawings, one or more example embodiments of the present disclosure will be described. The scales of the components shown in the drawings have different scales from the actual ones for convenience of explanation, and thus are not limited to the scales shown in the drawings.

FIG. 1 is a perspective view illustrating a transparent display device according to one or more example embodiments of the present disclosure.

Although a transparent display device 10 according to one or more example embodiments of the present disclosure is described as an organic light emitting display apparatus (OLED), the transparent display device 10 can be implemented as a liquid crystal display (LCD) apparatus, a quantum dot light emitting display (QLED) apparatus, or an electrophoretic display apparatus and is not limited thereto.

Referring to FIG. 1, the transparent display device 10 according to one or more example embodiments of the present disclosure includes a transparent display panel 100 and a light controlling panel 200, without being limited thereto. For example, the light controlling panel 200 can be disposed below the transparent display panel 100, without being limited thereto.

The transparent display panel 100 is provided with a plurality of pixels to display images. For example, a display area of the transparent display panel 100 includes a plurality of pixels P to display images. As an example, one or more additional components could be further included. The transparent display panel 100 can include a transmissive area in at least some areas. The transmissive area can allow most of the light incident from the outside to pass through. The transmissive area can be disposed between a plurality of pixels. The transparent display panel 100 allows external objects or background scenes to be visible due to the transmissive area.

The light controlling panel 200 can be disposed on at least one side of the transparent display panel 100 and can control light incident on the transparent display panel 100. The light controlling panel 200 can include an electrophoretic element that moves by an electric field. The light controlling panel 200 can control the movement of the electrophoretic element to implement a light-blocking mode and a light-transmitting mode. The electrophoretic element can switch from the light-blocking mode to the light-transmitting mode or from the light-transmitting mode to the light-blocking mode depending on whether a voltage is applied. The light controlling panel 200 can block incident light in the light-blocking mode and transmit incident light in the light-transmitting mode. Herein, the electrophoretic element is shown as an example, as long as the function of switching a light-blocking mode and a light-transmitting mode is satisfied, the light controlling panel 200 may be variously modified.

The light controlling panel 200 can be preferably disposed in a direction opposite to the direction in which the transparent display panel 100 emits light. For example, as shown in FIG. 1, when the transparent display panel 100 is a top emission type, the light controlling panel 200 can be disposed below the transparent display panel 100. For another example, when the transparent display panel 100 is a bottom emission type, the light controlling panel 200 can be disposed over the transparent display panel 100.

The light controlling panel 200 can be adhered to one surface of the transparent display panel 100. For example, the light controlling panel 200 can be adhered to one surface of the transparent display panel 100 using an adhesive layer, without being limited thereto. The adhesive layer can be a transparent adhesive film such as optically clear adhesive OCA or a transparent adhesive such as optically clear resin OCR, without being limited thereto.

In FIG. 1, it is illustrated that the light controlling panel 200 is disposed on one surface exposed to the outside of the transparent display panel 100, but it is not necessarily limited thereto. The light controlling panel 200 can be disposed within the transparent display panel 100. In this case, the light controlling panel 200 can be disposed on the top surface of any one of the plurality of layers provided in the transparent display panel 100. As an example, the light controlling panel 200 can be disposed between the substrate and the transistor of the transparent display panel 100. At this time, the light controlling panel 200 cannot include a separate substrate.

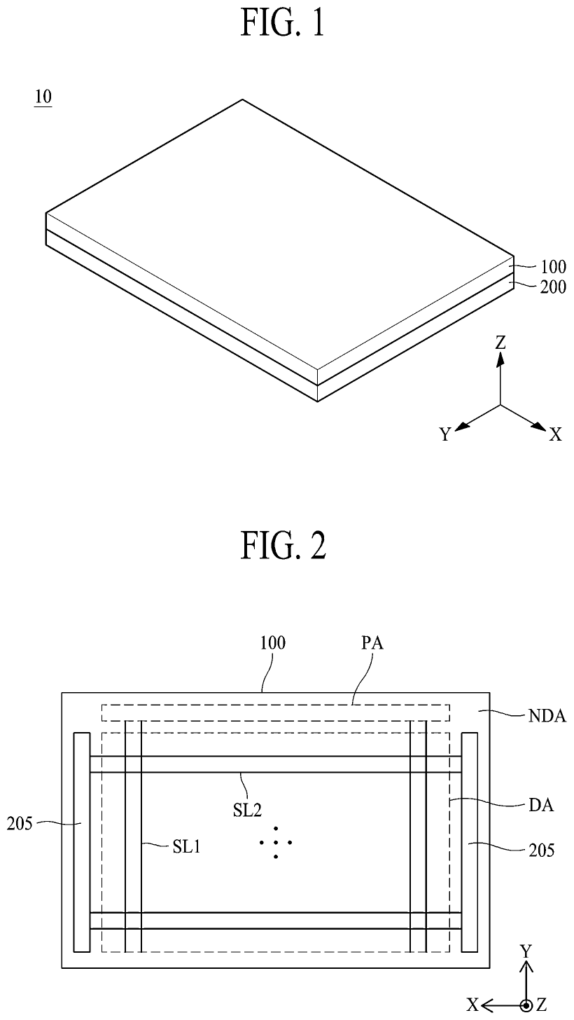

Hereinafter, the transparent display panel 100 will be described in more detail with reference to FIGS. 2 to 4.

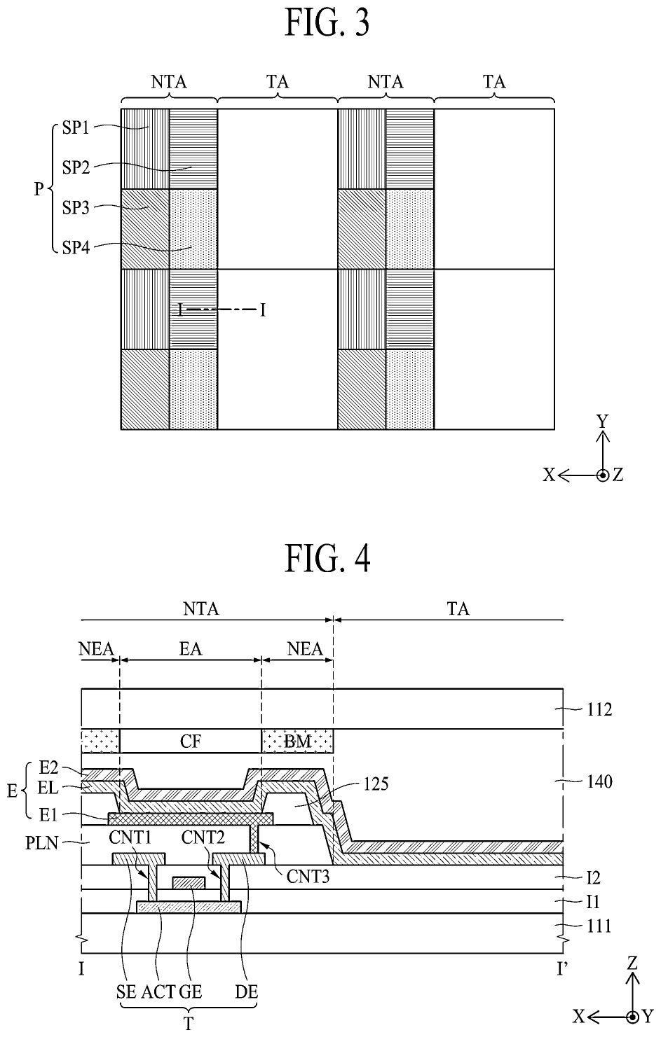

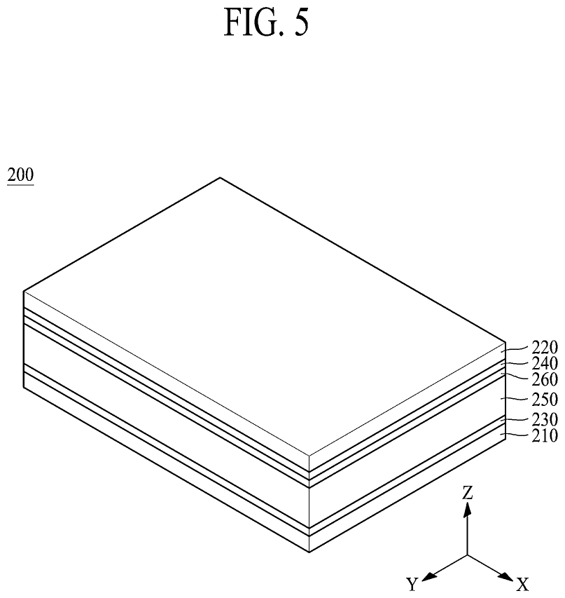

FIG. 2 is a plan view illustrating a transparent display panel according to one or more example embodiments of the present disclosure, FIG. 3 is a diagram illustrating an example of a transmissive area and a non-transmissive area provided in the display area of FIG. 2, and FIG. 4 is a cross-sectional view illustrating an example of I-I′ of FIG. 3.

Referring FIGS. 2 to 4, the transparent display panel 100 according to one or more example embodiments of the present disclosure can include a display area DA and a non-display NDA. The non-display NDA may be disposed around the display area DA. The display area DA includes a plurality of pixels P to display images, the non-display area NDA does not display images.

The display area DA can include first signal lines SL1, second signal lines SL2, and pixels, without being limited thereto. The non-display area NDA can include a pad area PA in which pads are arranged and at least one scan driver 205, without being limited thereto.

The first signal lines SL1 can extend in a first direction (e.g., Y-axis direction) in the display area DA. For example, the first signal lines SL1 can be data lines, but are not necessarily limited thereto. Also, the first signal lines SL1 can include at least one of a pixel power line, a common power line, and a reference line. The first direction can be Y-axis direction, without being limited thereto.

The second signal lines SL2 can extend in a second direction (e.g., X-axis direction) in the display area DA. The second signal lines SL2 can intersect the first signal lines SL1 in the display area DA. For example, the second signal lines SL2 can be scan lines, but are not necessarily limited thereto.

As shown in FIG. 3, the display area DA can include a transmissive area TA and a non-transmissive area NTA. The transmissive area TA is an area that transmits most of the light incident from the outside. The non-transmissive area NTA is an area that does not transmit most of the light incident from the outside. For example, the transmissive area TA can have a light transmittance greater than a % and the non-transmissive area NTA can have a light transmittance less than B %. At this time, a is greater than B. The transparent display device 10 can allow viewing of an object or background scenes that are located at a rear surface of the transparent display device 10 due to the transmissive area TA of the transparent display panel 100.

The non-transmissive area NTA includes an emission area EA in which a plurality of pixels P are provided to emit light. Each of the plurality of pixels P can include a plurality of sub-pixels, such as a first sub-pixel SP1, a second sub-pixel SP2, a third sub-pixel SP3, and a fourth sub-pixel SP4, without being limited thereto. The first sub-pixel SP1 and the second sub-pixel SP2 may be disposed adjacent to each in a first row, and the third sub-pixel SP3, and the fourth sub-pixel SP4 may be disposed adjacent to each other in a second row, without being limited thereto. Additionally, the arrangement order of each sub-pixels SP1, SP2, SP3, and SP4 can be changed in various ways. The first sub-pixel SP1 can include a first emission area EA that emits light of a first color, and the second sub-pixel SP2 can include a second emission area EA that emits light of a second color. The third sub-pixel SP3 can include a third emission area EA that emits third color light, and the fourth sub-pixel SP4 can include a fourth emission area EA that emits fourth color light.

For example, the first to fourth emission areas EA can emit light of different colors. For example, the first emission area EA can emit green light, and the second emission area EA can emit red light. The third emission area EA can emit blue light, and the fourth emission area EA can emit white light. However, it is not necessarily limited thereto. Additionally, the arrangement order of each sub-pixels SP1, SP2, SP3, and SP4 can be changed in various ways.

As shown in FIG. 4, each of the first to fourth sub-pixels SP1, SP2, SP3, and SP4 can include a transistor T and a light emitting device E between a lower substrate 111 and an upper substrate 112. The transistor T can be disposed on the lower substrate 111, and the light emitting device E can be disposed over the transistor T. The light emitting device E can include a lower electrode E1, an organic layer EL, and an upper electrode E2. For example, the organic layer EL may be disposed between the lower electrode E1 and the upper electrode E2.

The transistor T can include an active layer ACT disposed on the lower substrate 111, a first insulating film I1 disposed on the active layer ACT, a gate electrode GE disposed on the first insulating film I1, a second insulating film 12 disposed on the gate electrode GE, a source electrode SE, and a drain electrode DE. The source electrode SE and the drain electrode DE are disposed on the second insulating film 12 and connected to the active layer ACT through the first and second contact holes CNT1 and CNT2. For example, the first and second contact holes CNT1 and CNT2 may pass through the first insulating film I1, and the second insulating film 12. In FIG. 4, it is illustrated that the transistor T is a top gate type, but it is not necessarily limited thereto, the transistor T can be a bottom gate type in which the gate electrode GE is disposed below the active layer ACT.

The planarization film PLN can be disposed on the transistor T to planarize a step difference due to the transistor T and a plurality of signal lines. In this case, the light emitting device E may be disposed on the planarization film PLN. The planarization film PLN is disposed in the non-transmissive area NTA and cannot be disposed in at least a portion of the transmissive area TA. The planarization film PLN can cause refraction of light as it passes through, thereby impairing transparency. Accordingly, the transparent display panel 100 according to an embodiment of the present disclosure can increase transparency by removing a portion of the planarization film PLN from the transmissive area TA.

Meanwhile, in FIG. 4, it is illustrated that the first and second insulating films I1 and I2 disposed below the planarization film PLN are provided not only in the non-transmissive area NTA but also in the transmissive area TA, but are not necessarily limited thereto. In another example embodiment, some of the insulating films disposed below the planarization film PLN cannot be provided in at least a portion of the transmissive area TA in order to increase transparency. For example, the second insulating film 12 can be provided in the non-transmissive area NTA and cannot be provided in at least a portion of the transmissive area TA.

A bank 125 and the light emitting device E including the lower electrode E1, the organic layer EL, and the upper electrode E2 can be disposed on the planarization film PLN. Specifically, the lower electrode E1 may be disposed on the planarization film PLN, the bank 125 may be disposed on the lower electrode E1 and the planarization film PLN, the organic layer EL may be disposed on the bank 125 and the lower electrode E1, and the upper electrode E2 may be disposed on the organic layer EL, without being limited thereto.

The lower electrode E1 can be disposed for each sub-pixels SP1, SP2, SP3, and SP4 on the planarization film PLN, and cannot be disposed in the transmissive area TA. The lower electrode E1 can be electrically connected to the transistor T. Specifically, the lower electrode E1 can be connected to one of the source electrode SE and the drain electrode DE of the transistor T through the third contact hole CNT3 penetrating the planarization film PLN. For example, as shown in FIG. 4, the lower electrode E1 can be connected to the drain electrode DE of the transistor T through the third contact hole CNT3, without being limited thereto. A bank 125 is disposed between adjacent lower electrodes E1, so that the adjacent lower electrodes E1 can be electrically insulated from each other.

The lower electrode E1 can include a highly reflective metal material such as a stacked structure of aluminum and titanium (Ti/Al/Ti), a stacked structure of aluminum and ITO (ITO/Al/ITO), Ag alloy, a stacked structure of Ag alloy and ITO (ITO/Ag alloy), MoTi alloy, and a stacked structure of MoTi alloy and ITO (ITO/MoTi alloy/ITO). The Ag alloy can be an alloy of silver Ag, palladium Pd, and copper Cu. MoTi alloy can be an alloy of molybdenum Mo and titanium Ti. The lower electrode E1 can be an one of anode electrode and a cathode electrode, without being limited thereto. For example, the lower electrode E1 can be an anode electrode.

The bank 125 can be disposed on the planarization film PLN. Additionally, the bank 125 can be disposed to cover an edge of the lower electrode E1 and expose a portion of the lower electrode E1. Accordingly, the bank 125 can prevent the problem of reducing emission efficiency due to concentration of a current on an end of the lower electrode E1.

The bank 125 can define an emission area EA for each of the sub-pixels SP1, SP2, SP3, and SP4. The emission area EA of each of the sub-pixels SP1, SP2, SP3, and SP4 is formed by sequentially stacking the lower electrode E1, the organic layer EL, and the upper electrode E2. Holes from the lower electrode E1 and electrons from the upper electrode E2 combine with each other in the organic layer EL to emit light. In this case, the area where the bank 125 is formed does not emit light and can be a non-emission area NEA. The area where the bank 125 is not formed and the lower electrode E1 is exposed can be the emission area EA For example, the emission area EA may be disposed between the non-emission area NEA.

In the emission area EA of each of the sub-pixels SP1, SP2, SP3, and SP4, the organic layer EL can be dispose on the lower electrode E1. The organic layer EL can include a hole transporting layer, a light emitting layer, and an electron transporting layer. In this case, when the voltage is applied to the lower electrode E1 and the upper electrode E2, holes and electrons move to the light emitting layer through the hole transport layer and electron transport layer, respectively, and combine with each other in the light emitting layer to emit light.

In one embodiment, the organic layer EL can be a common layer commonly formed in the sub-pixels SP1, SP2, SP3, and SP4. At this time, the light emitting layer can be a white light emitting layer that emits white light, without being limited thereto.

In another example embodiment, the organic layer EL can include a light emitting layer formed for each sub-pixel SP1, SP2, SP3, and SP4. As one example, a first color light emitting layer emitting first color light can be formed in the first sub-pixel SP1, a second color light emitting layer emitting second color light can be formed in the second sub-pixel SP2, a third color light emitting layer emitting third color light can be formed in the third sub-pixel SP3, and a fourth color light emitting layer emitting fourth color light can be formed in the fourth sub-pixel SP4. For example, a green light emitting layer emitting green light can be formed in the first sub-pixel SP1, a red light emitting layer emitting red light can be formed in the second sub-pixel SP2, a blue light emitting layer emitting blue light can be formed in the third sub-pixel SP3, and a white light emitting layer emitting white light can be formed in the fourth sub-pixel SP4, without being limited thereto. In this case, the light emitting layer of the organic layer EL cannot be formed in the transmissive area TA.

The upper electrode E2 can be provided on the organic layer EL and the bank 125. The upper electrode E2 can be made of a transparent metal material (TCO, Transparent Conductive Material) such as ITO or IZO that can transmit light, or can be formed of a semi-transmissive conductive material such as magnesium Mg, silver Ag, or an alloy of magnesium Mg and silver Ag. When the upper electrode E2 is formed of the semi-transmissive conductive material, light emission efficiency can be increased due to a micro cavity. The upper electrode E2 can be one of an anode electrode and a cathode electrode For example, the upper electrode E2 can be cathode electrode.

An encapsulation film 140 can be disposed on the light emitting element E. The encapsulation film 140 can be formed on the upper electrode E2 to cover the upper electrode E2. The encapsulation film 140 serves to prevent oxygen or moisture from penetrating into the organic layer EL and the upper electrode E2. To this end, the encapsulation film 140 can include at least one inorganic film and at least one organic film.

A color filter CF can be disposed on one side of the upper substrate 112 facing the lower substrate 111. The color filter CF can be patterned for each sub-pixel SP1, SP2, SP3, and SP4. Specifically, the color filter CF can include a plurality of color filters corresponding to a plurality of the sub-pixels, such as a first color filter, a second color filter, a third color filter, and a fourth color filter. The first color filter can be arranged to correspond to the emission area EA of the first sub-pixel SP1. For example, the first color filter can be a green color filter that transmits green light, without being limited thereto. The second color filter can be arranged to correspond to the emission area EA of the second sub-pixel SP2. For example, the second color filter can be a red color filter that transmits red light, without being limited thereto. The third color filter CF3 can be arranged to correspond to the emission area EA of the third sub-pixel SP3. For example, the third color filter CF3 can be a blue color filter that transmits blue light, without being limited thereto. The fourth color filter can be arranged to correspond to the emission area EA4 of the fourth sub-pixel SP4. For example, the fourth color filter can be a white color filter that transmits white light, without being limited thereto. The white color filter can be made of a transparent organic material that transmits white light, but it is not necessarily limited thereto.

A black matrix BM can be disposed between the color filters CF. The black matrix BM is disposed between the sub-pixels SP1, SP2, SP3, and SP4 to prevent color mixing between adjacent sub-pixels SP1, SP2, SP3, and SP4. Additionally, the black matrix BM can prevent light incident from the outside from being reflected on a plurality of signal lines disposed between the sub-pixels SP1, SP2, SP3, and SP4.

In addition, the black matrix BM is disposed between the transmissive area TA and the plurality of sub-pixels SP1, SP2, SP3, and SP4 to prevent light emitted from each of the plurality of sub-pixels SP1, SP2, SP3, and SP4 from proceeding to the transmission area TA. In one embodiment, the black matrix BM cannot be disposed between the white sub-pixel and the transmissive area TA. The display panel 110 according to an embodiment of the present disclosure does not include the black matrix BM between the white sub-pixel and the transmissive area TA, thereby reducing the area where the black matrix BM is formed. Through this, the display panel 110 according to an embodiment of the present disclosure can improve transmittance. The black matrix BM can include a material that absorbs light, for example, a black dye that absorbs all light in the visible light wavelength range.

The color filter CF and the black matrix BM described above are not disposed in the transmissive area TA in order to maintain high light transmittance in the transmissive area TA. As shown in FIG. 4, the color filter CF may be disposed in the emission area EA of the non-transmissive area NTA, and the black matrix BM may be disposed in the non-emission area NEA of the non-transmissive area NTA, without being limited thereto.

As described above, the transparent display device 10 according to an embodiment of the present disclosure includes the transmissive area TA that allows most of the light incident from the outside to pass through and the emission area EA that emits light. As a result, in the embodiment of the present disclosure, an object or background scenes located on the rear surface or the front surface of the transparent display device 10 can be viewed through the transmissive areas TA of the transparent display device 10.

The scan driver 205 is connected to scan lines and supplies scan signals. The scan driver 205 can be disposed in the non-display area NDA outside one side or both sides of the display area DA of the transparent display panel 100. The scan driver 205 can be formed using a gate driver in panel GIP method or a tape automated bonding TAB method, without being limited thereto.

Hereinafter, the light controlling panel 200 will be described in more detail with reference to FIGS. 5 to 14.

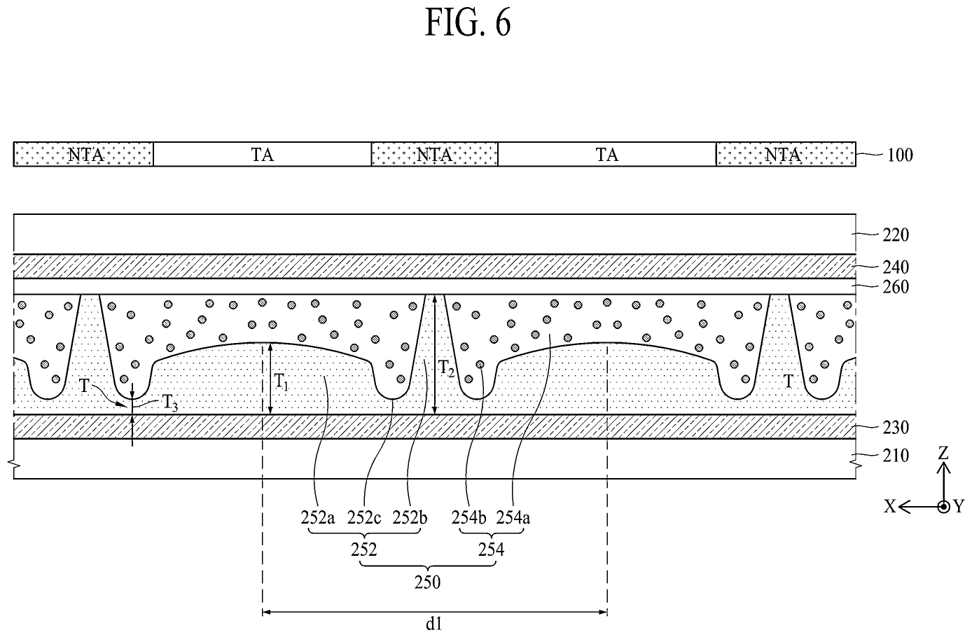

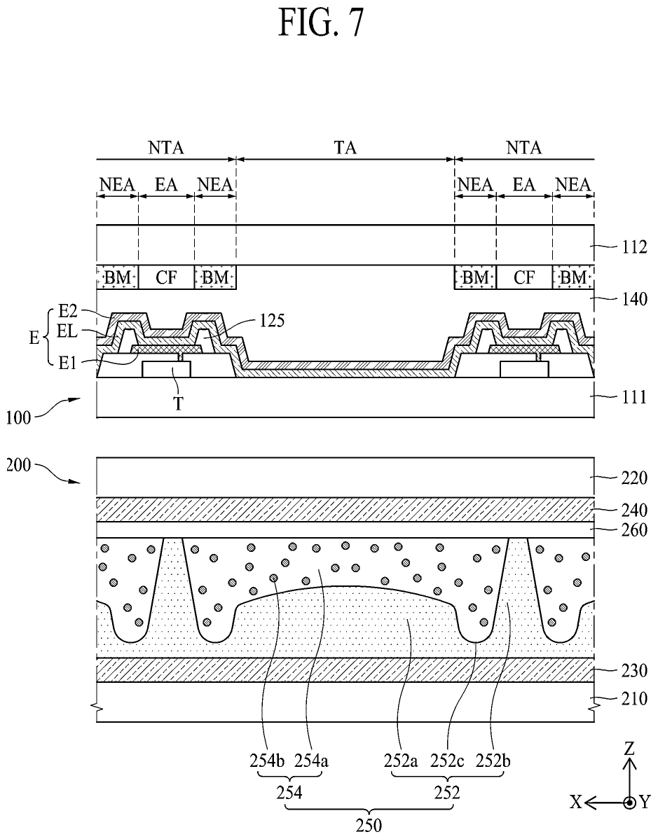

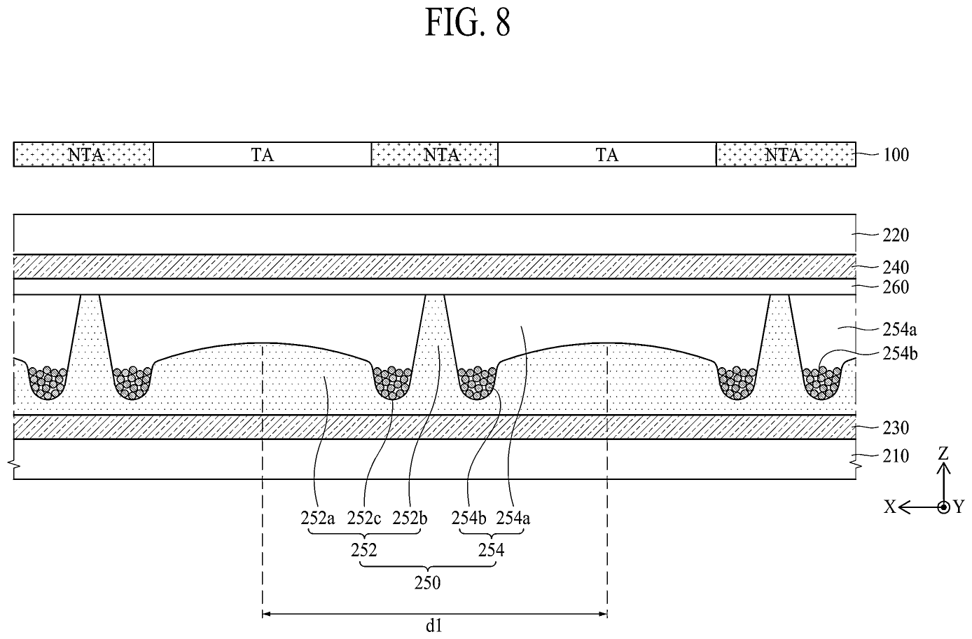

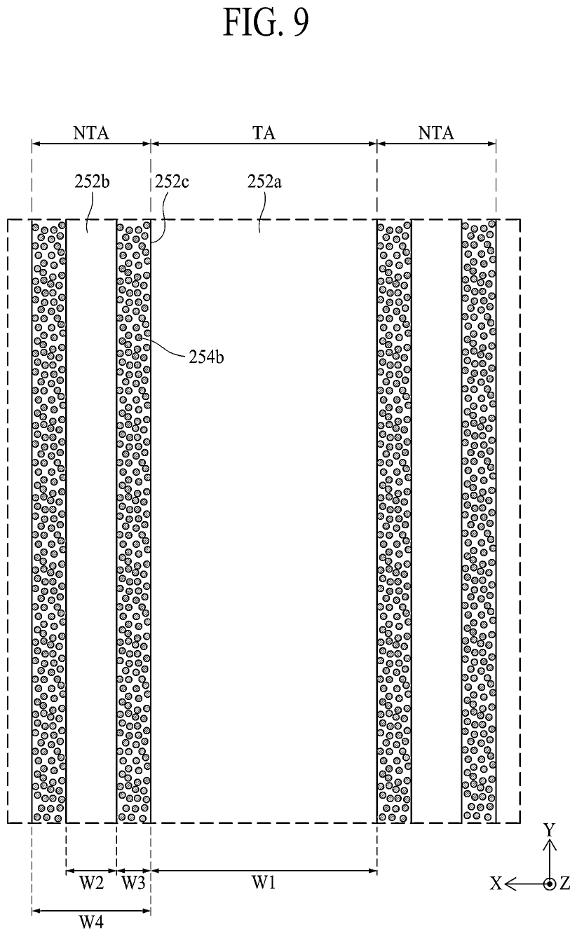

FIG. 5 is a perspective view illustrating a light controlling panel according to one or more example embodiments of the present disclosure, FIG. 6 is a cross-sectional view illustrating an example of one side of FIG. 5 in a light-blocking mode, FIG. 7 is a cross-sectional view illustrating an example of an arrangement relationship between components of a transparent display panel and components of the light controlling panel, FIG. 8 is a cross-sectional view illustrating an example of one side of FIG. 5 in a light-transmitting mode, and FIG. 9 is a plan view illustrating an example of a spacer, a guide pattern, and a groove.

Referring to FIGS. 5 to 9, the light controlling panel 200 according to an embodiment of the present disclosure can be implemented to operate in the light-transmitting mode that transmits incident light and the light-blocking mode that blocks incident light. In an embodiment of the present disclosure, it can be assumed that the light-blocking mode is a case where the light transmittance of the light controlling panel 200 is less than a % and the light-transmitting mode is a case where the light transmittance of the light controlling panel 200 is equal to or greater than B %. At this time, a can be less than B. The light transmittance of the light controlling panel 200 represents the ratio of light output to light incident on the light controlling panel 200.

To this end, the light controlling panel 200 according to an embodiment of the present disclosure includes a first substrate 210, a second substrate 220, a first electrode 230, a second electrode 240, and a dielectric layer 250 and an adhesive layer 260, without being limited thereto. For example, the first electrode 230, the second electrode 240, the dielectric layer 250 and the adhesive layer 260 may be disposed between the first substrate 210 and the second substrate 220.

Each of the first and second substrates 210 and 220 can be a glass substrate or a plastic film, or a flexible polymer film. When each of the first and second substrates 210 and 220 is a plastic film, cellulose resin such as triacetyl cellulose TAC or diacetyl cellulose DAC, etc., cyclo olefin polymer COP such as norbornene derivatives, etc., acrylic resin such as cyclo olefin copolymer COC or poly methylmethacrylate PMMA, etc., polyolefin such as polycarbonate PC, polyethylene PE, or polypropylene PP, etc., polyester such as polyvinyl alcohol PVA, poly ether sulfone PES, polyetheretherketone PEEK, polyetherimide PEI, polyethylenenaphthalate PEN, or polyethyleneterephthalate PET, etc., a sheet or film containing polyimide PI, polysulfone PSF, or fluoride resin, etc., but it is not necessarily limited thereto.

As shown in FIGS. 1 and 5, the light controlling panel 200 is disposed outside the transparent display panel 100 and can be provided in a separate configuration from the transparent display panel 100. In this case, the light controlling panel 200 can be formed in film type having a flexibility to disposed on one side of the transparent display panel 100 using a separate adhesive layer, but it is not necessarily limited thereto. In another example embodiment, the light controlling panel 200 can be disposed within the transparent display panel 100. The light controlling panel 200 can be disposed between the lower substrate 111 and the upper substrate 112 of the transparent display panel 100. In this case, the first substrate 210 and the second substrate 220 can be omitted in the light controlling panel 200.

The first electrode 230 can be disposed on one side of the first substrate 210 facing the second substrate 220. The second electrode 240 can be disposed on one side of the second substrate 220 facing the first substrate 210. Each of the first electrode 230 and the second electrode 240 can be formed as an integral electrode that overlaps the entire display area DA of the transparent display panel 100. In contrast, when each of the first electrode 230 and the second electrode 240 is formed with a plurality of pattern electrodes, expensive pattern electrode processing costs are incurred, and light blocking particles can be aggregated as an electric field is concentrated at both ends of the pattern electrode. Additionally, since a plurality of pattern electrodes must be controlled individually, the driving circuit is complicated.

The light controlling panel 200 according to an embodiment of the present disclosure includes each of the first electrode 230 and the second electrode 240 formed as one integral electrode, thereby reducing electrode processing costs and simplifying the driving circuit. Light blocking particles can be prevented from aggregating in an area overlapping the display area DA of the transparent display panel 100.

Each of the first electrode 230 and the second electrode 240 can be transparent electrode. Each of the first electrode 230 and the second electrode 240 can include silver oxide (e.g. AgO or Ag2O or Ag2O3), aluminum oxide (e.g. Al2O3), tungsten oxide (e.g. WO2 or WO3 or W2O3), magnesium oxide (e.g. MgO), molybdenum oxide (e.g. MoO3), zinc oxide (e.g. ZnO), tin oxide (e.g. SnO2), indium oxide (e.g. In2O3), chromium oxide (e.g. CrO3 or Cr2O3), antimony oxide (e.g. Sb2O3 or Sb2O5), titanium oxide (e.g. TiO2), nickel oxide (e.g. NiO), copper oxide (e.g. CuO or Cu2O), vanadium oxide (e.g. V2O3 or V2O5), cobalt oxide (e.g. CoO), iron oxide (e.g. Fe2O3 or Fe3O4), niobium oxide (e.g. Nb2O5), indium tin oxide (e.g. Indium Tin Oxide, ITO), indium zinc oxide (e.g. Indium Zinc Oxide, IZO), aluminum doped zinc oxide (e.g. ZAO), aluminum doped tin oxide (e.g. TAO), or antimony tin oxide (e.g. ATO), but it is not necessarily limited thereto.

The dielectric layer 250 can be disposed between the first electrode 230 and the second electrode 240 to implement a light-blocking mode or a light-transmitting mode depending on whether a voltage is applied to the first electrode 230 and the second electrode 240. Further, the adhesive layer 260 may be disposed between the second electrode 240 and the dielectric layer 250 to adhere the dielectric layer 250 to the second electrode 240. For example, the dielectric layer 250 can implement the light-transmitting mode when the voltage is applied to the first electrode 230 and the second electrode 240. On the other hand, the dielectric layer 250 can implement the light-blocking mode when no voltage is applied to the first electrode 230 and the second electrode 240.

As shown in FIG. 6, the dielectric layer 250 can include a first dielectric 252 and a second dielectric 254, without being limited thereto. The first dielectric 252 and the second dielectric 254 can be made of different dielectric materials. The light controlling panel 200 according to an embodiment of the present disclosure can control the direction of the electric field in a desired direction by utilizing the shape of the interface between the first dielectric 252 and the second dielectric 254 and the difference in dielectric permittivity between the first dielectric 252 and the second dielectric 254.

Specifically, the first dielectric 252 can be disposed on one side of the first electrode 230 facing the second electrode 240, and can be made of a first dielectric material having a first dielectric permittivity. The second dielectric 254 may be disposed on one side of the second electrode 240 facing the first electrode 230. Further, the adhesive layer 260 may be disposed between the second electrode 240 and the dielectric layer 250 to adhere the dielectric layer 250 to the second electrode 240. As shown in FIGS. 6 to 8, the first dielectric 252 can include a guide pattern 252a, a spacer 252b, and a groove 252c, without being limited thereto. As shown in FIGS. 6 to 8, the second dielectric 254 can include a solvent 254a and a plurality of light blocking particles 254b.

The guide pattern 252a can guide the plurality of light blocking particles 254b included in the second dielectric 254 to the groove 252c. The groove 252c may be disposed between the guide pattern 252a and the spacer 252b. Specifically, the top surface of the guide pattern 252a can be formed to be convex toward the second electrode 240. At this time, the top surface of the guide pattern 252a can be a curved surface, without being limited thereto. In this case, when the voltage is applied to the first electrode 230 and the second electrode 240, dielectric polarization occurs in the first dielectric material of the guide pattern 252a, and the dielectric polarization density varies depending on the shape of the top surface. Accordingly, the electric field can be generated in a direction inclined toward the groove 252c due to the convex shape of the guide pattern 252a.

The plurality of light blocking particles 254b included in the second dielectric 254 can move by the electric field generated between the first electrode 230 and the second electrode 240. When the voltage is applied to the first electrode 230 and the second electrode 240, the plurality of light blocking particles 254b can move to the groove 252c along the direction of the electric field. Accordingly, the plurality of light blocking particles 254b cannot be disposed on the area where the guide pattern 252a is disposed, and the area where the guide pattern 252a is disposed can have high light transmittance. Accordingly, external light can be transmitted through the area where the guide pattern 252a is disposed. The light passing through the light controlling panel 200 can be incident on the transparent display panel 100.

On the other hand, unlike the present disclosure, the guide pattern 252a can have a flat top surface. In the case that the top surface of the guide pattern 252a is a flat surface, when the voltage is applied to the first electrode 230 and the second electrode 240, the dielectric polarization density can be formed uniformly within the guide pattern 252a. In this case, the electric field can occur in a direction perpendicular to the first electrode 230. The plurality of light blocking particles 254b included in the second dielectric 254 move in a direction perpendicular to the first electrode 230 and the second electrode 240 when the voltage is applied to the first electrode 230 and the second electrode 240. The plurality of light blocking particles 254b move into the groove 252c in the area where the groove 252c is formed, but are distributed on the top surface of the guide pattern 252a in the area where the guide pattern 252a is formed. As the plurality of light blocking particles 254b are distributed in areas other than the grooves 252c, the light transmittance in the light-transmitting mode is significantly reduced when the top surface of the guide pattern 252a is a flat surface compared to when the top surface of the guide pattern 252a is a curved surface.

Additionally, the guide pattern 252a can have two inclined surfaces whose top surfaces are inclined with respect to the center. At this time, the two inclined surfaces can be flat and the center of the guide pattern 252a can have a sharp shape. When the slope of the two inclined surfaces is small, similar to a flat surface, the plurality of light blocking particles 254b cannot move to the groove 252c and can be distributed on the top surface of the guide pattern 252a. Accordingly, the light transmittance of the light controlling panel 200 can decrease in light-transmitting mode. Additionally, as the distance between the guide patterns 252a increases, it can become more difficult for the plurality of light blocking particles 254b to move into the groove 252c. The distance between the guide patterns 252a can be a distance between a center of one guide pattern 252a and a center of the adjacent other guide pattern 252a.

On the other hand, as the slopes of the two inclined surfaces increases, light can be transmitted and significantly refracted on the inclined surfaces of the guide pattern 252a in the light-transmitting mode. Accordingly, a double image in which one object is seen as two objects to the user can occur. That is, when the slopes of the two inclined surfaces of the guide pattern 252a are large, a double image in which one object is seen as two objects to the user can occur.

In the light controlling panel 200 according to an embodiment of the present disclosure, the top surface of the guide pattern 252a can be formed to have a curved surface, so that the direction of the electric field can be controlled to face toward the groove 252c when the voltage is applied to the first electrode 230 and the second electrode 240. Accordingly, in the light controlling panel 200 according to an embodiment of the present disclosure, the plurality of light blocking particles 254b can accurately move to the groove 252c and a high light transmittance can be achieved in light-transmitting mode. Additionally, in the light controlling panel 200 according to an embodiment of the present disclosure, the top surface of the guide pattern 252a is gently inclined, thereby preventing the double image from occurring.

A distance between a center of one guide pattern 252a and a center of the adjacent other guide pattern 252a can be a first distance d1. The first distance d1 can be the distance from the center of the top surface of one guide pattern 252a (or a point on the top surface with the largest separation distance from the first electrode 230) to the center of the top surface of the adjacent other guide pattern 252a (or a point on the top surface with the largest separation distance from the first electrode 230).

The guide pattern 252a can be disposed to overlap the transmissive area TA of the transparent display panel 100 in order to achieve high light transmittance in the light-transmitting mode. The guide pattern 252a can be disposed not to overlap the non-transmissive area NTA of the transparent display panel 100. In the light controlling panel 200 according to an embodiment of the present disclosure, in the light-transmitting mode, the plurality of light blocking particles 254b can move into the groove 252c and cannot be disposed in the area where the guide pattern 252a is disposed. In the light controlling panel 200 according to an embodiment of the present disclosure, external light can be transmitted through an area where the plurality of light blocking particles 254b are not disposed, that is, the area where the guide pattern 252a is disposed. Since the guide pattern 252a can be disposed to overlap the transmissive area TA of the transparent display panel 100, the light passing through the light controlling panel 200 is incident on the transparent display panel 100 and can pass through the transparent display panel 100 through the transmissive area TA of the transparent display panel 100.

In this way, external light can penetrate the transparent display device 10 through the area where the guide pattern 252a of the light controlling panel 200 is disposed and the transmissive area TA of the transparent display panel 100. In the transparent display device 10 according to an embodiment of the present disclosure, the guide pattern 252a of the light controlling panel 200 can be disposed to overlap with the transmissive area TA of the transparent display panel 100 in order to achieve high light transmittance in the light-transmitting mode. The guide pattern 252a of the light controlling panel 200 can be disposed not to overlap the non-transmissive area NTA of the transparent display panel 100. That is, as shown in FIG. 7, the guide pattern 252a of the light controlling panel 200 can be disposed not to overlap the light emitting device E of the transparent display panel 100. Additionally, the guide pattern 252a of the light controlling panel 200 can be disposed not to overlap the transistor T of the transparent display panel 100. Additionally, the guide pattern 252a of the light controlling panel 200 can be disposed not to overlap the color filter CF and black matrix BM of the transparent display panel 100.

As one example, in the light controlling panel 200 according to an embodiment of the present disclosure, one transmissive area TA of the transparent display panel 100 can overlap with one guide patterns 252a, without being limited thereto. Alternatively, one transmissive area TA of the transparent display panel 100 can overlap with a plurality of guide patterns 252a, which will be described in detail below.

The guide pattern 252a can be extended in one direction. In one embodiment, the guide pattern 252a can be extended in a first direction (e.g., Y-axis direction) as shown in FIG. 9, without being limited thereto. The groove 252c can be extended in the first direction parallel to the guide pattern 252a, without being limited thereto. For example, the guide pattern 252a can be extended parallel to the first signal lines SL1. The guide pattern 252a is disposed to overlap the transmissive area TA of the transparent display panel 100 and can have a first width W1. The first width W1 can be equal to or greater than the width in the first direction (e.g., Y-axis direction) of the transmissive area TA of the transparent display panel 100. In this case, the light controlling panel 200 according to an embodiment of the present disclosure can include only one guide pattern 252a between two adjacent spacers 252b.

In FIG. 9, it is illustrated that the guide pattern 252a is extended in a first direction (e.g., Y-axis direction), but it is not necessarily limited thereto. The extension direction of the guide pattern 252a can vary depending on the shape of the transmissive area TA in the transparent display panel 100. As shown in FIG. 3, the transparent display panel 100 can include the transmissive areas TA disposed in a line along the first direction (e.g., Y-axis direction). In this case, the guide pattern 252a can be extended in the first direction (e.g., Y-axis direction) as shown in FIG. 9.

However, unlike shown in FIG. 3, the transparent display panel 100 can include the transmissive areas TA disposed in a line along a second direction (e.g., X-axis direction). In this case, the guide pattern 252a can be extended in the second direction (e.g., X-axis direction).

The spacer 252b can be disposed between the first electrode 230 and the second electrode 240 to maintain the gap between the first electrode 230 and the second electrode 240. The spacer 252b can be disposed between guide patterns 252a arranged adjacently on a plane.

The groove 252c can be disposed on at least one side of the spacer 252b. For example, the groove 252c can be disposed on one side of the spacer 252b, or the spacer 252b can be disposed between the two grooves 252c. The groove 252c can be disposed on the side of the spacer 252b facing the guide pattern 252a. At this time, the spacer 252b can be spaced apart from the guide pattern 252a with the groove 252c interposed therebetween. For example, the spacer 252b can be disposed between two guide patterns 252a. One groove 252c can be disposed on one side of the spacer 252b facing one guide pattern 252a, and the spacer 252b can be spaced apart from the one guide pattern 252a with the one groove 252c interposed therebetween. In addition, another groove 252c can be disposed on the other side of the spacer 252b facing the other guide pattern 252a, and the spacer 252b can be spaced apart from the other guide pattern 252a with the other groove 252c interposed therebetween. The spacer 252b can be disposed between the two grooves 252c.

The spacer 252b can be disposed to overlap the non-transmissive area NTA of the transparent display panel 100. The spacer 252b can be extended in one direction in an area overlapping the non-transmissive area NTA of the transparent display panel 100. In one embodiment, the spacer 252b can be extended in the first direction (e.g., Y-axis direction) as shown in FIG. 9, without being limited thereto. For example, the spacer 252b can be extended parallel to the first signal lines SL. The spacer 252b can have a second width W2 and be extended in the first direction (e.g., Y-axis direction) parallel to the guide pattern 252a and may be disposed between the two grooves 252c. The groove 252c can be extended in the first direction parallel to the guide pattern 252a, without being limited thereto. The second width W2 can be smaller than the first width W1 of the guide pattern 252a and smaller than the width in the first direction (e.g., Y-axis direction) of the non-transmissive area NTA of the transparent display panel 100, without being limited thereto.

In FIG. 9, it is illustrated that the spacer 252b is extended in the first direction (e.g., Y-axis direction), but it is not necessarily limited thereto. The direction in which the spacer 252b is extended can vary depending on the shape of the non-transmissive area NTA in the transparent display panel 100. As shown in FIG. 3, the transparent display panel 100 can have non-transmissive area NTA disposed in a line along the first direction (e.g., Y-axis direction). In this case, the spacer 252b can be extended in the first direction (e.g., Y-axis direction) as shown in FIG. 9.

However, in the transparent display panel 100, unlike shown in FIG. 3, the non-transmissive areas NTA can be disposed in a line along the second direction (e.g., X-axis direction). In this case, the spacer 252b can be extended in the second direction (e.g., X-axis direction).

The groove 252c can be disposed between the guide pattern 252a and the spacer 252b. The groove 252c can be formed concavely toward the first electrode 230 and can gather the light blocking particles 254b included in the second dielectric 254 in the light-transmitting mode. Specifically, when the voltage is applied to the first electrode 230 and the second electrode 240, the plurality of light blocking particles 254b included in the second dielectric 254 can move to the groove 252c along the direction of the electric field.

The groove 252c can be disposed to overlap the non-transmissive area NTA of the transparent display panel 100. That is, as shown in FIG. 7, at least a portion of the groove 252c of the light controlling panel 200 can be disposed to overlap with the light emitting device E of the transparent display panel 100. Additionally, at least a portion of the groove 252c of the light controlling panel 200 can be disposed to overlap with the transistor T of the transparent display panel 100. Additionally, at least a portion of the groove 252c of the light controlling panel 200 can be disposed to overlap the color filter CF and the black matrix BM of the transparent display panel 100. However, the present application is not limited thereto. Also, the spacer 252b disposed between the grooves 252c is disposed to overlap the non-transmissive area NTA of the transparent display panel 100.

The plurality of light blocking particles 254b can move by the electric field generated between the first electrode 230 and the second electrode 240. When the voltage is applied to the first electrode 230 and the second electrode 240, the plurality of light blocking particles 254b can move into the groove 252c along the direction of the electric field. At this time, the area where the groove 252c is disposed can be blocked from transmitting external light by the plurality of light blocking particles 254b. For this reason, when the area where the groove 252c is disposed overlaps the transmissive area TA of the transparent display panel 100, in the light-transmitting mode, the light transmittance of the transparent display device 10 can decrease due to the plurality of light blocking particles 254b gathered in the groove 252c of the first dielectric 252 included in the light controlling panel 200. Through this, the light controlling panel 200 according to an embodiment of the present disclosure can prevent the grooves 252c from overlapping with the transmissive area TA of the transparent display panel 100. In the light controlling panel 200 according to an embodiment of the present disclosure, the groove 252c and the spacer 252b disposed between the grooves 252c are disposed to overlap the non-transmissive area NTA of the transparent display panel 100, and thus, in the light-transmitting mode, it is possible to prevent the light transmittance from being reduced due to the light blocking particles 254b gathered in the groove 252c.

The groove 252c can be extended in one direction. In one embodiment, the groove 252c can be extended in the first direction (e.g., Y-axis direction) as shown in FIG. 9. For example, the groove 252c can be extended parallel to the first signal lines SL1. The groove 252c can have a third width W3 and be extended in the first direction (e.g., Y-axis direction) parallel to the guide pattern 252a. and the spacer 252b and may be disposed between the guide pattern 252a and the spacer 252b. The third width W3 can be smaller than the first width W1 of the guide pattern 252a and smaller than the width in the first direction (e.g., Y-axis direction) of the non-transmissive area NTA of the transparent display panel 100, without being limited thereto.

More specifically, a fourth width W4 or a region where the groove 252c and the spacer 252b are disposed can be smaller than the width in the first direction (e.g., Y-axis direction) of the non-transmissive area NTA of the transparent display panel 100, without being limited thereto. For example, when two grooves 252c are adjacently disposed with the spacer 252b therebetween, the fourth width W4 which is the sum of the width W3 of each of the two grooves 252c and the width W2 of the spacer 252b can be smaller than the width in the first direction (e.g., Y-axis direction) of the non-transmissive area NTA of the transparent display panel 100. Through this, the light controlling panel 200 according to an embodiment of the present disclosure can prevent the grooves 252c from overlapping with the transmissive area TA of the transparent display panel 100, and further, the groove 252c and the spacer 252b disposed between the grooves 252c are disposed to overlap the non-transmissive area NTA of the transparent display panel 100, and thus, in the light-transmitting mode, it is possible to prevent the light transmittance of the transparent display device 10 from being reduced due to the light blocking particles 254b gathered in the groove 252c.

In FIG. 9, it is illustrated that the groove 252c is extended in the first direction (e.g., Y-axis direction), but it is not necessarily limited thereto. The extension direction of the groove 252c can vary depending on the shape of the non-transmissive area NTA in the transparent display panel 100. As shown in FIG. 3, the transparent display panel 100 can include the non-transmissive area NTA disposed in a line along the first direction (e.g., Y-axis direction). In this case, the groove 252c can be extended in the first direction (e.g., Y-axis direction) as shown in FIG. 9.

However, in the transparent display panel 100, unlike shown in FIG. 3, the non-transmissive area NTA can be disposed in a line along the second direction (e.g., X-axis direction). In this case, the groove 252c can be extended in the second direction (e.g., X-axis direction).

In one embodiment, the guide pattern 252a, the spacer 252b, and the groove 252c included in the first dielectric 252 can be formed as single body, without being limited thereto. The guide pattern 252a, the spacer 252b, and the groove 252c included in the first dielectric 252 can be made of the same first dielectric material, without being limited thereto. The guide pattern 252a, the spacer 252b, and the groove 252c included in the first dielectric 252 can be formed simultaneously through an imprinting process, without being limited thereto. Alternatively, the guide pattern 252a, the spacer 252b, and the groove 252c included in the first dielectric 252 can be formed by different processes. The light controlling panel 200 according to an embodiment of the present disclosure simultaneously forms the guide pattern 252a, the spacer 252b, and the groove 252c through the imprinting process, thereby reducing the manufacturing process cost and the manufacturing process time due to the simplicity of the manufacturing process, and further reducing the production energy. In addition, the light controlling panel 200 according to an embodiment of the present disclosure can reduce the manufacturing process and the generation of greenhouse gases due to the manufacturing process can be reduced, thereby improving ESG (Environment/Social/Governance) qualities.

Each of the guide pattern 252a, the spacer 252b, and the groove 252c can be imprinted to have different thicknesses on one surface of the first electrode 230. The guide pattern 252a can have a first thickness T1, and the spacer 252b can have a second thickness T2 greater than the first thickness T1, without being limited thereto. At this time, the second thickness T2 can correspond to the separation distance between the first electrode 230 and the second electrode 240. The groove 252c is disposed between the guide pattern 252a and the spacer 252b, and the area where the groove 252c is disposed can have a third thickness T3. The third thickness T3 can be smaller than the first thickness T1 of the guide pattern 252a, but can be greater than 0, without being limited thereto. That is, the first dielectric 252 can be formed to have a predetermined third thickness T3 without exposing the first electrode 230 in the area where the groove 252c is formed.

Since the light controlling panel 200 according to an embodiment of the present disclosure includes a first dielectric 252 having a predetermined thickness in the area where the groove 252c is formed, when a voltage is applied to the first electrode 230 and the second electrode 240, the impact applied when the light blocking particles 254b gather into the groove 252c can be alleviated, thereby preventing the light blocking particles 254b from being damaged.

The second dielectric 254 can be disposed on one side of the second electrode 240 facing the first electrode 230. As shown in FIGS. 6 to 8, the second dielectric 254 can include a solvent 254a and a plurality of light blocking particles 254b distributed within the solvent 254a, and the solvent 254a comprises a second dielectric material having a second dielectric permittivity, without being limited thereto.

The solvent 254a is disposed on the first dielectric 252 and can fill the space formed by the step difference among the guide pattern 252a, the spacer 252b, and the groove 252c. The solvent 254a can be made of a second dielectric material having a second dielectric permittivity. The second dielectric permittivity can be different from the first dielectric permittivity of the first dielectric material included in the first dielectric 252. In one embodiment, the second dielectric permittivity can be smaller than the first dielectric permittivity.

Meanwhile, the greater the difference between the first dielectric permittivity and the second dielectric permittivity, the easier it can be for the light blocking particles 254b to move into the groove 252c of the first dielectric 252 in the light-transmitting mode. Specifically, in the light controlling panel 200, a voltage can be applied to the first electrode 230 and the second electrode 240 in the light-transmitting mode, and the dielectric polarization can occur in the first dielectric 252 and the solvent 254a of the second dielectric 254. The greater the difference between the first dielectric permittivity and the second dielectric permittivity, the greater the difference in dielectric polarization density at the interface between the first dielectric 252 and the solvent 254a of the second dielectric 254 can be. The electric field is generated in a direction tilted toward the groove 252c due to the convex shape of the guide pattern 252a, and the greater the difference in the dielectric polarization density at the interface between the first dielectric 252 and the solvent 254a of the second dielectric 254, the greater the tilt of the electric field direction can be. Accordingly, the plurality of light blocking particles 254b can better move into the groove 252c of the first dielectric 252 when switching from the light-blocking mode to the light-transmitting mode. Accordingly, in the light controlling panel 200 according to an embodiment of the present disclosure, the plurality of light blocking particles 254b can better move into the groove 252c of the first dielectric 252 and a high light transmittance can be achieved in light-transmitting mode.

Meanwhile, the greater the difference between the first dielectric permittivity and the second dielectric permittivity, the easier it can be for the light blocking particles 254b to move into the groove 252c of the first dielectric 252 in the light-transmitting mode. In one embodiment, the difference between the first dielectric permittivity and the second dielectric permittivity can be 15 or more, without being limited thereto. By ensuring that the difference in dielectric permittivity between the first dielectric 252 and the solvent 254a of the second dielectric 254 is greater than or equal to 15, the light control panel 200 can allow the plurality of light blocking particles 254b to move completely into the grooves 252c of the first dielectric 252 in the light-transmitting mode. The light controlling panel 200 can increase light transmittance in light-transmitting mode.

In one embodiment, the top surface of the first dielectric 252 can be subjected plasma treatment to have hydrophilicity. The first dielectric 252 can be in direct contact with the solvent 254a of the second dielectric 254 on its top surface. As the dielectric permittivity difference between the first dielectric 252 and the solvent 254a of the second dielectric 254 increases, the adhesion between the first dielectric 252 and the solvent 254a of the second dielectric 254 can decrease. A decrease in the adhesion between the first dielectric 252 and the second dielectric 254 can increase the possibility that the second dielectric 254 is detached from the first dielectric 252. To prevent this, the first dielectric 252 can be plasma treated so that the top surface of the first dielectric 252 in contact with the solvent 254a of the second dielectric 254 changes from hydrophobic to hydrophilic. Through this, the adhesion between the first dielectric 252 and the second dielectric 254, which have a large dielectric permittivity difference, can be improved, and the second dielectric 254 can be prevented from peeling off from the first dielectric 252. Specifically, the solvent 254a of the second dielectric 254 can be prevented from peeling off from the first dielectric 252

The plurality of light blocking particles 254b can be negatively or positively charged and distributed within the solvent 254a, and can block light incident from the outside. The plurality of light blocking particles 254b can be an electrophoretic material, for example, carbon particles, without being limited thereto.

An area where the plurality of light blocking particles 254b are distributed can vary depending on whether the voltage is applied to the first electrode 230 and the second electrode 240. When no voltage is applied to the first electrode 230 and the second electrode 240, the plurality of light blocking particles 254b can be evenly dispersed in the solvent 254a as shown in FIG. 6. Since the plurality of light blocking particles 254b are distributed over the entire area where the solvent 254a is provided, the light-blocking mode can be implemented by external light being blocked by the plurality of light blocking particles 254b over the entire area. The external light does not penetrate the light controlling panel 200 and cannot enter the transmissive area TA as well as the non-transmissive area NTA of the transparent display panel 100, thereby implementing the light-blocking mode.

On the other hand, when the voltage is applied to the first electrode 230 and the second electrode 240, as shown in FIG. 8, the plurality of light blocking particles 254b can be gathered in the groove 252c of the first dielectric 252 along the direction of the electric field. The groove 252c can be disposed to overlap the non-transmissive area NTA of the transparent display panel 100, without being limited thereto. The plurality of light blocking particles 254b can be distributed only in the area where the groove 252c is formed and cannot be distributed in area where the groove 252c is not formed. The external light can be transmitted in area excluding the groove 252c, thereby implementing the light-transmitting mode. The light passing through the light controlling panel 200 can penetrate through the transparent display panel 100 through the transmissive area TA of the transparent display panel 100. Through this, a user located in front surface of the transparent display device 10 can see objects located on the rear surface of the transparent display device 10.

The adhesive layer 260 is disposed between the second electrode 240 and the dielectric layer 250 to adhere the dielectric layer 250 to the second electrode 240. The adhesive layer 260 can be a transparent adhesive film such as optically clear adhesive OCA or a transparent adhesive such as optically clear resin OCR, without being limited thereto.

The light controlling panel 200 according to an embodiment of the present disclosure can implement the light-blocking mode and the light-transmitting mode using an electrophoretic element. Through this, the light controlling panel 200 according to an embodiment of the present disclosure can implement the transparent display device 10 that allows the user to see objects located on the rear surface of the transparent display device 10 in the light-transmitting mode. At the same time, the light controlling panel 200 according to an embodiment of the present disclosure can enable the transparent display device 10 to display images with a high contrast ratio in the light-blocking mode.

In addition, the light controlling panel 200 according to an embodiment of the present disclosure can include each of the first electrode 230 and the second electrode 240 as one integral electrode, thereby reducing the cost of processing the electrode and simplifying a driving circuit. In addition, in the light controlling panel 200 according to an embodiment of the present disclosure, the edge of the electrode is not disposed in the display area DA of the transparent display panel 100, and thus, it is possible to prevent the plurality of light blocking particles 254b from clumping in an area that overlaps with the display area DA of the transparent display panel 100.

In addition, in the light controlling panel 200 according to an embodiment of the present disclosure, the top surface of the guide pattern 252a of the first dielectric 252 can be formed to have a convex curved surface facing the second electrode 240 between the two grooves 252c. Through this, in the light controlling panel 200 according to an embodiment of the present disclosure, when the voltage is applied to the first electrode 230 and the second electrode 240, the plurality of light blocking particles 254b can move into the groove 252c and cannot remain on the top surface of the guide pattern 252a. The light controlling panel 200 according to an embodiment of the present disclosure can increase light transmittance in the light-transmitting mode.

In addition, in the light controlling panel 200 according to an embodiment of the present disclosure, the top surface of the guide pattern 252a is gently inclined, thereby preventing the double image from occurring.

In addition, in the light controlling panel 200 according to an embodiment of the present disclosure, the guide pattern 252a of the first dielectric 252 can be disposed to overlap the transmissive area TA of the transparent display panel 100, thereby achieving a high light transmittance in the light-transmitting mode.

In addition, in the light controlling panel 200 according to an embodiment of the present disclosure, the groove 252c of the first dielectric 252 can be disposed to overlap the non-transmissive area NTA of the transparent display panel 100, so that the light transmittance can be prevented from decreasing due to the light blocking particles 254b gathered in the groove 252c of the first dielectric 252 in the light-transmitting mode.

In addition, in the light controlling panel 200 according to an embodiment of the present disclosure, the first dielectric 252 can be formed to have a predetermined thickness in the area where the groove 252c is formed, so that the impact applied when the light blocking particles 254b gather into the groove 252c can be alleviated, thereby preventing the light blocking particles 254b from being damaged.

In addition, in the light controlling panel 200 according to an embodiment of the present disclosure, the guide pattern 252a, the spacer 252b, and the groove 252c can be formed simultaneously through an imprinting process. Through this, the light controlling panel 200 according to an embodiment of the present disclosure can reduce the manufacturing process cost and the manufacturing process time due to the simplicity of the manufacturing process, and further reduce the production energy. In addition, the light controlling panel 200 according to an embodiment of the present disclosure can reduce the manufacturing process and the generation of greenhouse gases due to the manufacturing process can be reduced, thereby improving ESG (Environment/Social/Governance) qualities.

In addition, in the light controlling panel 200 according to an embodiment of the present disclosure, the difference in dielectric permittivity between the first dielectric 252 and the second dielectric 254 can be large, so that the plurality of light blocking particles 254b can completely move into the groove 252c of the first dielectric 252.

In addition, in the light controlling panel 200 according to an embodiment of the present disclosure, by ensuring that the difference in dielectric permittivity between the first dielectric 252 and the solvent 254a of the second dielectric 254 is greater than or equal to 15, the light control panel 200 can allow the plurality of light blocking particles 254b to move completely into the groove 252c of the first dielectric 252 in the light-transmitting mode. The light controlling panel 200 can increase light transmittance in light-transmitting mode.

As shown in FIGS. 6 to 9, the light controlling panel 200 according to an embodiment of the present disclosure can have the guide pattern 252a of the first dielectric 252 aligned with the transmissive area TA of the transparent display panel 100, and the groove 252c of the first dielectric 252 aligned with the non-transmissive area NTA of the transparent display panel 100. Also, the light controlling panel 200 according to an embodiment of the present disclosure can have the spacer 252b disposed to overlap the non-transmissive area NTA of the transparent display panel 100. However, it is not necessarily limited thereto.

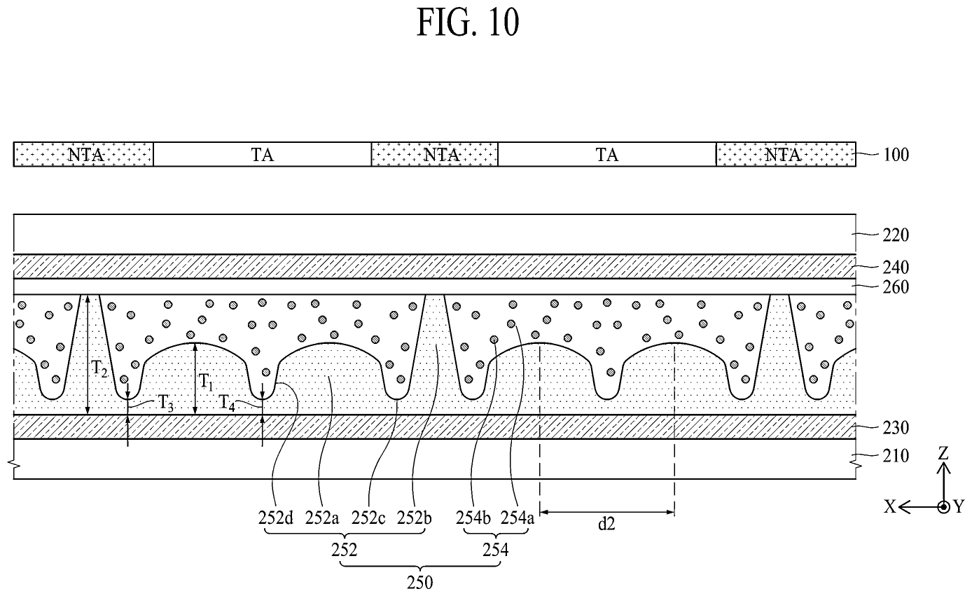

The light controlling panel 200 can be implemented in a film type having a flexibility. However, it is not necessarily limited thereto. A precise process can be required to align the film-type light controlling panel 200 and the transparent display panel 100 as described above. In order to facilitate the process, the structure of the first dielectric 252 may be modified so that the light controlling panel 200 according to another example embodiment of the present disclosure can be disposed on the transparent display panel 100 without considering the positions of the transmissive area TA and the non-transmissive area NTA of the transparent display panel 100. Hereinafter, the light controlling panel 200 according to another example embodiment of the present disclosure will be described in more detail with reference to FIGS. 10 to 13.

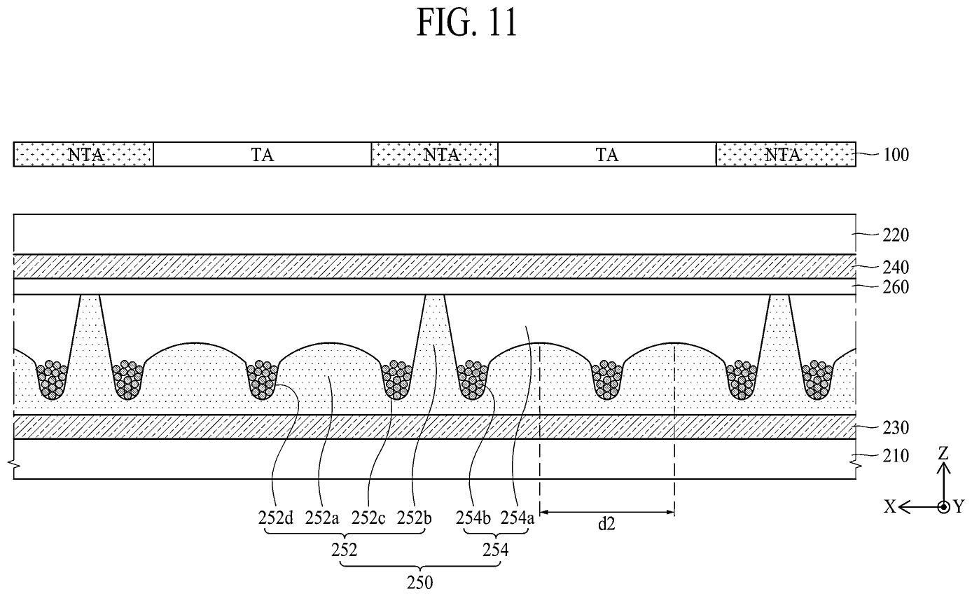

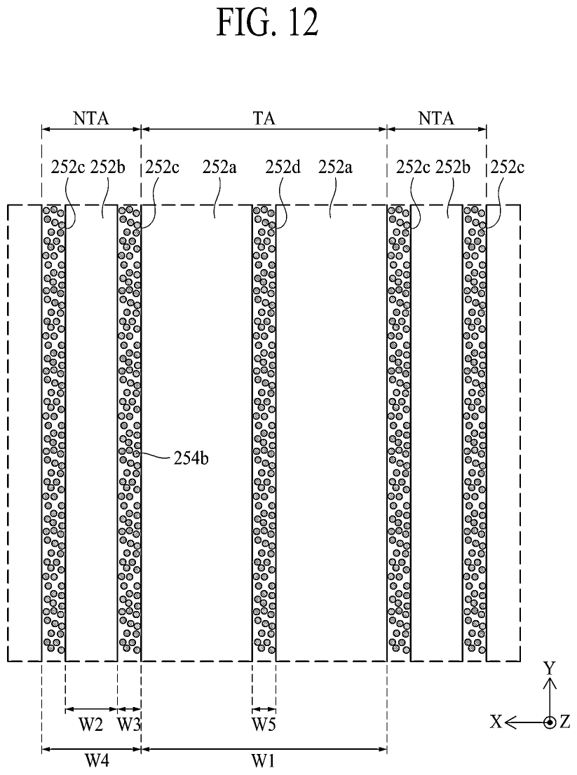

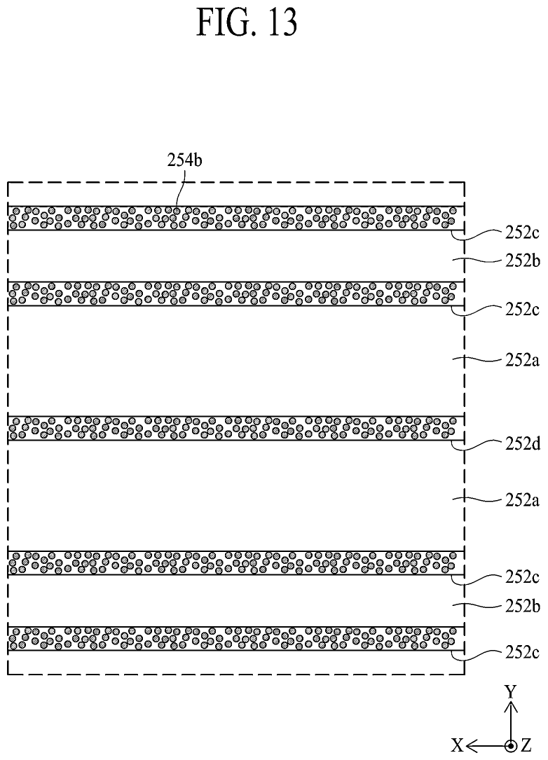

FIG. 10 is a cross-sectional view illustrating another example of one side of FIG. 5 in a light-blocking mode, FIG. 11 is a cross-sectional view illustrating another example of one side of FIG. 5 in a light-transmitting mode, FIG. 12 is a plan view illustrating another example of a spacer, a guide pattern, and a groove, FIG. 13 is a plan view illustrating another example of a spacer, a guide pattern, and a groove.

Referring FIGS. 10 to 13, the light controlling panel 200 according to another example embodiment of the present disclosure includes a first substrate 210, a second substrate 220, a first electrode 230, and a second electrode 240, a dielectric layer 250, and an adhesive layer 260, without being limited thereto.

The light controlling panel 200 according to another example embodiment of the present disclosure differs only in the dielectric layer 250 compared to the light controlling panel 200 according to an embodiment of the present disclosure shown in FIGS. 6 to 9, with the other components being substantially the same. Hereinafter, the differences will be mainly described, and descriptions for substantially the same components will be omitted or briefly given.

The dielectric layer 250 can be disposed between the first electrode 230 and the second electrode 240 to implement the light-blocking mode or the light-transmitting mode depending on whether a voltage is applied to the first electrode 230 and the second electrode 240. Further, the adhesive layer 260 may be disposed between the second electrode 240 and the dielectric layer 250 to adhere the dielectric layer 250 to the second electrode 240. For example, the dielectric layer 250 can implement the light-transmitting mode when the voltage is applied to the first electrode 230 and the second electrode 240. On the other hand, the dielectric layer 250 can implement the light-blocking mode when no voltage is applied to the first electrode 230 and the second electrode 240.

As shown in FIG. 10, the dielectric layer 250 can include a first dielectric 252 and a second dielectric 254, without being limited thereto. The first dielectric 252 and the second dielectric 254 can be made of different dielectric materials. The light controlling panel 200 according to another example embodiment of the present disclosure can control the direction of the electric field in a desired direction by utilizing the shape of the interface between the first dielectric 252 and the second dielectric 254 and the difference in dielectric permittivity between the first dielectric 252 and the second dielectric 254. Additionally, the light controlling panel 200 according to another example embodiment of the present disclosure can have a structure that does not require alignment between the components of the first dielectric 252 and the transmissive area TA of the transparent display panel 100.

Specifically, the first dielectric 252 can be disposed on one side of the first electrode 230 facing the second electrode 240, and can be made of a first dielectric material having a first dielectric permittivity. The second dielectric 254 may be disposed on one side of the second electrode 240 facing the first electrode 230. Further, the adhesive layer 260 may be disposed between the second electrode 240 and the dielectric layer 250 to adhere the dielectric layer 250 to the second electrode 240. As shown in FIGS. 10 and 11, the first dielectric 252 can include a guide pattern 252a, a spacer 252b, a first groove 252c, and a second groove 252d, without being limited thereto. As shown in FIGS. 10 and 11, the second dielectric 254 can include a solvent 254a and a plurality of light blocking particles 254b.

The guide pattern 252a can guide the plurality of light blocking particles 254b included in the second dielectric 254 to the first groove 252c or the second groove 252d. Specifically, the top surface of the guide pattern 252a can be formed to be convex toward the second electrode 240. At this time, the top surface of the guide pattern 252a can be a curved surface. In this case, when the voltage is applied to the first electrode 230 and the second electrode 240, dielectric polarization occurs in the first dielectric material of the guide pattern 252a, and the dielectric polarization density varies depending on the shape of the top surface. Accordingly, the electric field can be generated in a direction inclined toward the first groove 252c or the second groove 252d due to the convex shape of the guide pattern 252a.

The plurality of light blocking particles 254b included in the second dielectric 254 can move by the electric field generated between the first electrode 230 and the second electrode 240. When the voltage is applied to the first electrode 230 and the second electrode 240, the plurality of light blocking particles 254b can move to the first groove 252c or the second groove 252d along the direction of the electric field. Accordingly, the plurality of light blocking particles 254b cannot be disposed on the area where the guide pattern 252a is disposed, and the area where the guide pattern 252a is disposed can have high light transmittance. Accordingly, external light can be transmitted through the area where the guide pattern 252a is disposed. The light passing through the light controlling panel 200 can be incident on the transparent display panel 100.

When the guide pattern 252a has a flat top surface, the light transmittance of the light controlling panel 200 can decrease in light-transmitting mode, and when the slopes of the two inclined surfaces of the guide pattern 252a are large, a double image in which one object is seen as two objects to the user can occur.

In this way, in the light controlling panel 200 according to another example embodiment of the present disclosure, the top surface of the guide pattern 252a can be formed to have a curved surface, so that the direction of the electric field can be controlled to face toward the first groove 252c or the second groove 252d when the voltage is applied to the first electrode 230 and the second electrode 240. Accordingly, in the light controlling panel 200 according to another example embodiment of the present disclosure, the plurality of light blocking particles 254b can accurately move to the first groove 252c or the second groove 252d and a high light transmittance can be achieved in light-transmitting mode. Additionally, in the light controlling panel 200 according to another example embodiment of the present disclosure, the top surface of the guide pattern 252a is gently inclined, thereby preventing the double image from occurring.

At least a portion of the guide pattern 252a can be disposed to overlap the transmissive area TA of the transparent display panel 100 in order to achieve high light transmittance in the light-transmitting mode. The guide pattern 252a can be disposed not to overlap the non-transmissive area NTA of the transparent display panel 100. In the light controlling panel 200 according to another example embodiment of the present disclosure, in the light-transmitting mode, the plurality of light blocking particles 254b can move into the first groove 252c or the second groove 252d and cannot be disposed in the area where the guide pattern 252a is disposed. In the light controlling panel 200 according to another example embodiment of the present disclosure, external light can be transmitted through an area where the plurality of light blocking particles 254b are not disposed, that is, the area where the guide pattern 252a is disposed. Since at least a portion of the guide pattern 252a of the light controlling panel 200 can be disposed to overlap the transmissive area TA of the transparent display panel 100, the light passing through the light controlling panel 200 is incident on the transparent display panel 100 and can pass through the transparent display panel 100 through the transmissive area TA of the transparent display panel 100.

In this way, the external light can penetrate the transparent display device 10 through the area where the guide pattern 252a of the light controlling panel 200 is disposed and the transmissive area TA of the transparent display panel 100. In the transparent display device 10 according to another example embodiment of the present disclosure, at least a portion of the guide pattern 252a of the light controlling panel 200 can be disposed to overlap with the transmissive area TA of the transparent display panel 100, thereby achieving a high light transmittance in the light-transmitting mode. The guide pattern 252a of the light controlling panel 200 can be disposed not to overlap the non-transmissive area NTA of the transparent display panel 100.

Unlike the light controlling panel 200 shown in FIGS. 6 to 9, in the light controlling panel 200 according to another example embodiment of the present disclosure, one transmissive area TA of the transparent display panel 100 can overlap with a plurality of guide patterns 252a. That is, in the light controlling panel 200 according to another example embodiment of the present disclosure, a plurality of guide patterns 252a can be disposed in an area overlapping one transmissive area TA.

Additionally, in the light controlling panel 200 according to another example embodiment of the present disclosure, a plurality of the guide patterns 252a can be disposed between two adjacent spacers 252b. For example, two guide patterns 252a can be disposed between two spacers 252b disposed adjacently as shown in FIGS. 10 and 11, but it is not necessarily limited thereto. Three or more guide patterns 252a can be disposed between two adjacent spacers 252b.

Each of the guide patterns 252a can be extended in one direction. In one embodiment, the guide patterns 252a can be extended parallel to each other in a first direction (e.g., Y-axis direction) as shown in FIG. 12, without being limited thereto. The groove 252c can be extended in the first direction parallel to each of the guide patterns 252a, without being limited thereto. For example, each of the guide patterns 252a can be extended parallel to the first signal lines SL1. At least a portion of each of the guide patterns 252a is disposed to overlap the transmissive area TA of the transparent display panel 100 and each of the guide patterns 252a can have a first width W1. The first width W1 can be smaller than the width in the first direction (e.g., Y-axis direction) of the transmissive area TA of the transparent display panel 100.

In the light controlling panel 200 according to another example embodiment of the present disclosure, the pitch of the guide pattern 252a can be reduced. In the light controlling panel 200 according to another example embodiment of the present disclosure, a distance between a center of one guide pattern 252a and a center of the adjacent other guide pattern 252a can be a second distance d2. The second distance d2 can be smaller than the width in the first direction (e.g., Y-axis direction) of the transmissive area TA of the transparent display panel 100. The second distance d2 can be smaller than the first distance d1. The second distance d2 can be the distance from the center of the top surface of one guide pattern 252a (or a point on the top surface with the largest separation distance from the first electrode 230) to the center of the top surface of the adjacent other guide pattern 252a (or a point on the top surface with the largest separation distance from the first electrode 230). In the light controlling panel 200 according to another example embodiment of the present disclosure, the moving distance of the light blocking particles 254b is reduced when switching from the light-blocking mode to the light-transmitting mode, so that the light blocking particles 254b can be better gathered in the grooves 252c and 252d.

Meanwhile, in FIG. 12, it is illustrated that the guide patterns 252a are extended in the first direction (e.g., Y-axis direction), but they are not necessarily limited thereto.

In the light controlling panel 200 according to another example embodiment of the present disclosure, at least a portion of the guide pattern 252a can overlap with the transmissive area TA of the transparent display panel 100 in order to achieve high light transmittance in the light-transmitting mod, and does not necessarily need to be aligned with the transmissive area TA of the transparent display panel 100. The guide pattern 252a can be disposed not to overlap the non-transmissive area NTA of the transparent display panel 100. Accordingly, in the light controlling panel 200 according to another example embodiment of the present disclosure, the guide pattern 252a can be disposed regardless of the shape of the transmissive area TA of the transparent display panel 100. In another example embodiment, each of the guide patterns 252a can be extended in a second direction (e.g., X-axis direction) as shown in FIG. 13. For example, each of the guide patterns 252a can be extended parallel to the second signal lines SL2, but are not necessarily limited thereto.

The spacer 252b can be disposed between the first electrode 230 and the second electrode 240 to maintain the gap between the first electrode 230 and the second electrode 240. The spacer 252b can be disposed between guide patterns 252a disposed adjacently on a plane.

The first groove 252c can be disposed on at least one side of the spacer 252b. The first groove 252c can be disposed on the side of the spacer 252b facing the guide pattern 252a. At this time, the spacer 252b can be spaced apart from the guide pattern 252a with the first groove 252c interposed therebetween. For example, the spacer 252b can be disposed between two guide patterns 252a. One first groove 252c can be disposed on one side of the spacer 252b facing one guide pattern 252a, and the spacer 252b can be spaced apart from the one guide pattern 252a with the one first groove 252c interposed therebetween. In addition, another first groove 252c can be disposed on the other side of the spacer 252b facing the other guide pattern 252a, and the spacer 252b can be spaced apart from the other guide pattern 252a with the other first groove 252c interposed therebetween. The spacer 252b can be disposed between the two first grooves 252c.

At least a portion of the spacer 252b can be disposed to overlap the non-transmissive area NTA of the transparent display panel 100. The spacer 252b can be extended in one direction in an area overlapping the non-transmissive area NTA of the transparent display panel 100. In one embodiment, the spacer 252b can be extended in the first direction (e.g., Y-axis direction) as shown in FIG. 12, without being limited thereto. For example, the spacer 252b can be extended parallel to the first signal lines SL. The spacer 252b can have a second width W2 and be extended in the first direction (e.g., Y-axis direction) parallel to the guide pattern 252a and may be disposed between the two grooves 252c. The grooves 252c and 252d can be extended in the first direction parallel to the guide pattern 252a, without being limited thereto. The second width W2 can be smaller than the first width W1 of the guide pattern 252a and smaller than the width in the first direction (e.g., Y-axis direction) of the non-transmissive area NTA of the transparent display panel 100, without being limited thereto.

Meanwhile, in FIG. 12, it is illustrated that the spacer 252b is extended in a first direction (e.g., Y-axis direction), but it is not necessarily limited thereto.

In the light controlling panel 200 according to another example embodiment of the present disclosure, the spacer 252b does not necessarily need to be aligned with the non-transmissive area NTA of the transparent display panel 100. Accordingly, in the light controlling panel 200 according to another example embodiment of the present disclosure, the spacer 252b can be disposed regardless of the shape of the non-transmissive area NTA of the transparent display panel 100. In another example embodiment, the spacer 252b can be extended in the second direction (e.g., X-axis direction) as shown in FIG. 13. For example, the spacer 252b can be extended parallel to the second signal lines SL2.

The first groove 252c can be disposed between the guide pattern 252a and the spacer 252b, and the second groove 252d can be disposed between adjacent guide patterns 252a. At least a portion of each of the first groove 252c and the second groove 252d can overlap the transmissive area TA of the transparent display panel 100, and the remaining portion can overlap the non-transmissive area NTA of the transparent display panel 100.

The first groove 252c and the second groove 252d are formed concavely toward the first electrode 230, and can gather the light blocking particles 254b included in the second dielectric 254 in light-transmitting mode. The plurality of light blocking particles 254b can move by the electric field generated between the first electrode 230 and the second electrode 240. When the voltage is applied to the first electrode 230 and the second electrode 240, the plurality of light blocking particles 254b can move into the first groove 252c or the second groove 252d along the direction of the electric field.

Each of the first groove 252c and the second groove 252d can be extended in one direction. In one embodiment, each of the first groove 252c and the second groove 252d can be extended in the first direction (e.g., Y-axis direction) as shown in FIG. 12. For example, each of the first groove 252c and the second groove 252d can be extended parallel to the first signal lines SL1. The first groove 252c can have a third width W3 and be extended in a first direction (e.g., Y-axis direction) parallel to the guide pattern 252a. The second groove 252d can have a fifth width W5 and can be extended in the first direction (e.g., Y-axis direction) parallel to the guide pattern 252a. Each of the third width W3 and the fifth width W5 can be smaller than the first width W1 of the guide pattern 252a, and can be smaller than the width in the first direction (e.g., Y-axis direction) of the non-transmissive area NTA of the transparent display panel 100 without being limited thereto.

Additionally, the first groove 252c and the second groove 252d can have same width, that is, the third width W3 and the fifth width W5 can be the same, but are not necessarily limited thereto. The first groove 252c and the second groove 252d can have different widths. For example, the second groove 252d disposed between the guide patterns 252a can be formed to have a smaller width than the first groove 252c because the second groove 252d has a larger area overlapping with the transmissive area TA of the transparent display panel 100 than the first groove 252c. Through this, the light controlling panel 200 according to another example embodiment of the present disclosure can minimize the reduction in the light transmittance of the transparent display device 10 due to the light blocking particles 254b gathered in the second groove 252d in the light-transmitting mode.

Meanwhile, in FIG. 12, it is illustrated that the first groove 252c and the second groove 252d are extended in the first direction (e.g., Y-axis direction), but are not necessarily limited thereto.

In the light controlling panel 200 according to another embodiment of the present disclosure, at least a portion of the guide pattern 252a can overlap with the transmissive area TA of the transparent display panel 100 in order to achieve high light transmittance in the light-transmitting mode, and does not necessarily need to be aligned with the transmissive area TA of the transparent display panel 100. Accordingly, in the light controlling panel 200 according to another embodiment of the present disclosure, the guide pattern 252a can be disposed regardless of the shape of the transmissive area TA of the transparent display panel 100.

In the light controlling panel 200 according to another example embodiment of the present disclosure, the first groove 252c and the second groove 252d do not necessarily need to be aligned with the non-transmissive area NTA of the transparent display panel 100. Accordingly, in the light controlling panel 200 according to another example embodiment of the present disclosure, the first groove 252c and the second groove 252d can be disposed regardless of the shape of the non-transmissive area NTA of the transparent display panel 100. In another example embodiment, each of the first groove 252c and the second groove 252d can be extended in the second direction (e.g., X-axis direction) as shown in FIG. 13, but are not necessarily limited thereto. For example, each of the first groove 252c and the second groove 252d can be extended parallel to the second signal lines SL2, but are not necessarily limited thereto.

As a result, in the light controlling panel 200 according to another example embodiment of the present disclosure, the guide pattern 252a, the spacer 252b, the first groove 252c, and the second groove 252d included in the first dielectric 252 can be formed to extend in the first direction (e.g., Y-axis direction) as shown in FIG. 12, but is not necessarily limited thereto. In the light controlling panel 200 according to another example embodiment of the present disclosure, the guide pattern 252a, the spacer 252b, the first groove 252c, and the second groove 252d included in the first dielectric 252 can be formed to extend in a second direction (e.g., X-axis direction) as shown in FIG. 13. In this case, the spacer 252b extending in the second direction (e.g., X-axis direction) can block the plurality of light blocking particles 254b from moving downward due to gravity. Accordingly, the plurality of light blocking particles 254b can be evenly distributed in the solvent 254a of the second dielectric 254 without being clumped downward by gravity. The light controlling panel 200 according to another example embodiment of the present disclosure can prevent the plurality of light blocking particles 254b included in the second dielectric 254 from clumping to one side and can maintain a uniform ratio of the plurality of light blocking particles 254b, so that the light blocking rate can be maintained uniformly in light-blocking mode.

In one embodiment, the guide pattern 252a, the spacer 252b, the first groove 252c, and the second groove 252d included in the first dielectric 252 can be formed as single body, without being limited thereto. The guide pattern 252a, the spacer 252b, the first groove 252c, and the second groove 252d included in the first dielectric 252 can be made of the same first dielectric material, without being limited thereto. The guide pattern 252a, the spacer 252b, the first groove 252c, and the second groove 252d included in the first dielectric 252 can be formed simultaneously through an imprinting process first groove 252c, and the second groove 252d included in the first dielectric 252 can be formed by different processes. The light controlling panel 200 according to another example embodiment of the present disclosure simultaneously forms the guide pattern 252a, the spacer 252b, the first groove 252c, and the second groove 252d through the imprinting process, thereby reducing the manufacturing process cost and the manufacturing process time due to the simplicity of the manufacturing process, and further reducing the production energy. In addition, the light controlling panel 200 according to another example embodiment of the present disclosure can reduce the manufacturing process and the generation of greenhouse gases due to the manufacturing reduced, thereby ESG process can be improving (Environment/Social/Governance) qualities.

Each of the guide pattern 252a, the spacer 252b, the first groove 252c, and the second groove 252d can be imprinted to have different thicknesses on one surface of the first electrode 230. The guide pattern 252a can have a first thickness T1, and the spacer 252b can have a second thickness T2 greater than the first thickness T1, without being limited thereto. At this time, the second thickness T2 can correspond to the separation distance between the first electrode 230 and the second electrode 240. The first groove 252c is disposed between the guide pattern 252a and the spacer 252b, and the area where the first groove 252c is disposed can have a third thickness T3. The second groove 252d is disposed between the guide patterns 252a, and the area where the second groove 252d is disposed can have a fourth thickness T4. The fourth thickness T4 can be smaller than the first thickness T1 of the guide pattern 252a, but can be greater than 0, without being limited thereto. That is, the first dielectric 252 can be formed to have a predetermined third thickness T3 and T4 without exposing the first electrode 230 in the area where the first groove 252c and the second groove 252d are formed.

Since the light controlling panel 200 according to another example embodiment of the present disclosure includes a first dielectric 252 having a predetermined thickness in the area where the first groove 252c and the second groove 252d are formed, when a voltage is applied to the first electrode 230 and the second electrode 240, the impact applied when the light blocking particles 254b gather into the grooves 252c and 252d can be alleviated, thereby preventing the light blocking particles 254b from being damaged.

The second dielectric 254 can be disposed on one side of the second electrode 240 facing the first electrode 230. As shown in FIG. 10, the second dielectric 254 can include a solvent 254a and a plurality of light blocking particles 254b distributed within the solvent 254a, and the solvent 254a comprises a second dielectric material having a second dielectric permittivity, without being limited thereto.

The solvent 254a is disposed on the first dielectric 252 and can fill the space formed by the step difference among the guide pattern 252a, the spacer 252b, the first groove 252c, and the second groove 252d. The solvent 254a can be made of a second dielectric material having a second dielectric permittivity. The second dielectric permittivity can be different from the first dielectric permittivity of the first dielectric material included in the first dielectric 252. In one embodiment, the second dielectric permittivity can be smaller than the first dielectric permittivity.

Meanwhile, the greater the difference between the first dielectric permittivity and the second dielectric permittivity, the easier it can be for the light blocking particles 254b to move into the grooves 252c and 252d of the first dielectric 252 in the light-transmitting mode. In one embodiment, the difference between the first dielectric permittivity and the second dielectric permittivity can be 15 or more, without being limited thereto. By ensuring that the difference in dielectric permittivity between the first dielectric 252 and the solvent 254a of the second dielectric 254 is greater than or equal to 15, the light control panel 200 can allow the plurality of light blocking particles 254b to move completely into the grooves 252c and 252d of the first dielectric 252 in the light-transmitting mode. The light controlling panel 200 can increase light transmittance in light-transmitting mode.

In one embodiment, the top surface of the first dielectric 252 can be subjected plasma treatment to have hydrophilicity. The first dielectric 252 can be plasma treated so that the top surface of the first dielectric 252 in contact with the solvent 254a of the second dielectric 254 changes from hydrophobic to hydrophilic. Through this, the adhesion between the first dielectric 252 and the second dielectric 254, which have a large dielectric permittivity difference, can be improved, and the second dielectric 254 can be prevented from peeling off from the first dielectric 252. Specifically, the solvent 254a of the second dielectric 254 can be prevented from peeling off from the first dielectric 252.

The plurality of light blocking particles 254b can be negatively or positively charged and distributed within the solvent 254a, and can block light incident from the outside. The plurality of light blocking particles 254b can be an electrophoretic material, for example, carbon particles, without being limited thereto.

An area where the plurality of light blocking particles 254b are distributed can vary depending on whether the voltage is applied to the first electrode 230 and the second electrode 240. When no voltage is applied to the first electrode 230 and the second electrode 240, the plurality of light blocking particles 254b can be evenly dispersed in the solvent 254a as shown in FIG. 10. Since the plurality of light blocking particles 254b are distributed over the entire area where the solvent 254a is provided, the light-blocking mode can be implemented by external light being blocked by the plurality of light blocking particles 254b over the entire area. The external light does not penetrate the light controlling panel 200 and cannot enter the transmissive area TA as well as the non-transmissive area NTA of the transparent display panel 100, thereby implementing the light-blocking mode.

On the other hand, when the voltage is applied to the first electrode 230 and the second electrode 240, as shown in FIG. 11, the plurality of light blocking particles 254b can be gathered in the grooves 252c and 252d of the first dielectric 252 along the direction of the electric field. The groove 252c can be disposed to overlap the non-transmissive area NTA of the transparent display panel 100, and the groove 252d can be disposed to overlap the transmissive area TA of the transparent display panel 100, without being limited thereto. The plurality of light blocking particles 254b can be distributed only in the area where the grooves 252c and 252d are formed and cannot be distributed in area where the grooves 252c and 252d are not formed. The external light can be transmitted in area excluding the grooves 252c and 252d, thereby implementing the light-transmitting mode. The light passing through the light controlling panel 200 can penetrate through the transparent display panel 100 through the transmissive area TA of the transparent display panel 100. Through this, a user located in front surface of the transparent display device 10 can see objects located on the rear surface of the transparent display device 10.

The light controlling panel 200 according to another example embodiment of the present disclosure can implement the light-blocking mode and the light-transmitting mode using an electrophoretic element. Through this, the light controlling panel 200 according to another example embodiment of the present disclosure can implement the transparent display device 10 that allows the user to see objects located on the rear surface of the transparent display device 10 in the light-transmitting mode. At the same time, the light controlling panel 200 according to another example embodiment of the present disclosure can enable the transparent display device 10 to display images with a high contrast ratio in the light-blocking mode.

In addition, the light controlling panel 200 according to another example embodiment of the present disclosure can include each of the first electrode 230 and the second electrode 240 as one integral electrode, thereby reducing the cost of processing the electrode and simplifying a driving circuit. In addition, in the light controlling panel 200 according to another example embodiment of the present disclosure, the edge of the electrode is not disposed in the display area DA of the transparent display panel 100, and thus, it is possible to prevent the plurality of light blocking particles 254b from clumping in an area that overlaps with the display area DA of the transparent display panel 100.

In addition, in the light controlling panel 200 according to another example embodiment of the present disclosure, the top surface of the guide pattern 252a of the first dielectric 252 can be formed to have a convex curved surface facing the second electrode 240 between the two grooves 252c and 252d. Through this, in the light controlling panel 200 according to another example embodiment of the present disclosure, when the voltage is applied to the first electrode 230 and the second electrode 240, the plurality of light blocking particles 254b can move into the grooves 252c and 252d and cannot remain on the top surface of the guide pattern 252a. The light controlling panel 200 according to another example embodiment of the present disclosure can increase light transmittance in the light-transmitting mode.

In addition, in the light controlling panel 200 according to another embodiment of the present disclosure, the top surface of the guide pattern 252a is gently inclined, thereby preventing the double image from occurring.

In addition, in the light controlling panel 200 according to another example embodiment of the present disclosure, at least a portion of the guide pattern 252a of the first dielectric 252 can be disposed to overlap the transmissive area TA of the transparent display panel 100, thereby achieving a high light transmittance in the light-transmitting mode.

In addition, in the light controlling panel 200 according to another example embodiment of the present disclosure, at least a portion of each of the grooves 252c and 252d of the first dielectric 252 can be disposed to overlap the non-transmissive area NTA of the transparent display panel 100, so that the light transmittance can be prevented from decreasing due to the light blocking particles 254b gathered in the grooves 252c and 252d of the first dielectric 252 in the light-transmitting mode.

In addition, in the light controlling panel 200 according to another example embodiment of the present disclosure, the width of the guide pattern 252a can be reduced and the second groove 252d can be disposed between the guide patterns 252a. Since the light controlling panel 200 according to another example embodiment of the present disclosure include the second groove 252d, the amount of the light blocking particles 254b to be gathered in the first groove 252c disposed between the guide pattern 252a and the spacer 252b can be reduced, and thus, the width of the first groove 252c can be reduced. Accordingly, it can be easier for the light controlling panel 200 according to another example embodiment of the present disclosure to align the first groove 252c within the non-transmissive area NTA of the transparent display panel 100. That is, the light controlling panel 200 according to another example embodiment of the present disclosure can align the first groove 252c within the non-transmissive area NTA of the transparent display panel 100 even if a slight process error occurs.

In the light controlling panel 200 according to another example embodiment of the present disclosure, the first groove 252c cannot be completely aligned within the non-transmissive area NTA of the transparent display panel 100 due to a process error. However, even in this case, in the light controlling panel 200 according to another example embodiment of the present disclosure, the light blocking particles 254b are also dispersed in the second groove 252d, thereby preventing the transmittance from being greatly reduced in only some areas in the light-transmitting mode and achieving uniform transmittance.

In addition, in the light controlling panel 200 according to another example embodiment of the present disclosure, the first dielectric 252 can be formed to have a predetermined thickness in the area where the grooves 252c and 252d are formed, so that the impact applied when the light blocking particles 254b gather into the grooves 252c and 252d can be alleviated, thereby preventing the light blocking particles 254b from being damaged.

In addition, in the light controlling panel 200 according to another example embodiment of the present disclosure, the guide pattern 252a, the spacer 252b, the first groove 252c, and the second groove 252d can be formed simultaneously through an imprinting process. Through this, the light controlling panel 200 according to an embodiment of the present disclosure can reduce the manufacturing process cost and the manufacturing process time due to the simplicity of the manufacturing process, and further reduce the production energy. In addition, the light controlling panel 200 according to another example embodiment of the present disclosure can reduce the manufacturing process and the generation of greenhouse gases due to the manufacturing process can be reduced, thereby improving ESG (Environment/Social/Governance) qualities.

In addition, in the light controlling panel 200 according to another example embodiment of the present disclosure, the difference in dielectric permittivity between the first dielectric 252 and the second dielectric 254 can be large, so that the plurality of light blocking particles 254b can completely move into the grooves 252c and 252d of the first dielectric 252.

In addition, in the light controlling panel 200 according to another embodiment of the present disclosure, by ensuring that the difference in dielectric permittivity between the first dielectric 252 and the solvent 254a of the second dielectric 254 is greater than or equal to 15, the light control panel 200 can allow the plurality of light blocking particles 254b to move completely into the grooves 252c and 252d of the first dielectric 252 in the light-transmitting mode. The light controlling panel 200 can increase light transmittance in light-transmitting mode.

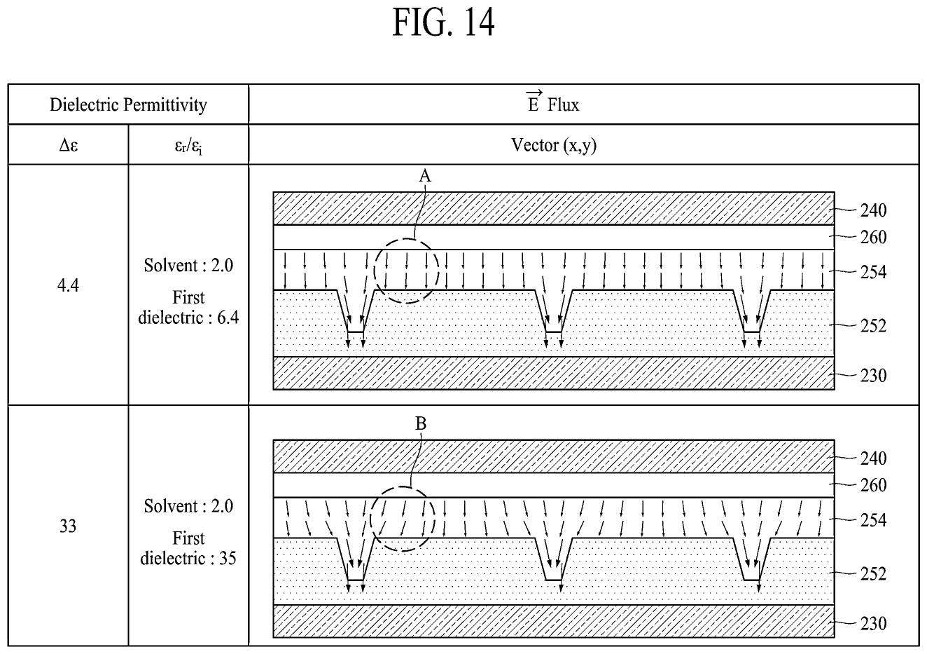

FIG. 14 is a diagram illustrating the difference in electric field direction depending on the shape of the guide pattern of the first dielectric.

Referring to FIG. 14, when the top surface of the guide pattern 252a of the first dielectric 252 is flat, when the voltage is applied to the first electrode 230 and the second electrode 240, the electric field can occur in a direction perpendicular to the first electrode 230 like in area A. Since the plurality of light blocking particles 254b move in a direction perpendicular to the first electrode 230 along the electric field direction, the plurality of light blocking particles 254b move into the groove 252c in the area where the groove 252c is formed and some of the plurality of light blocking particles 254b are distributed on the top surface of the guide pattern 252a.

On the other hand, in the light controlling panel 200 according to the present disclosure, the top surface of the guide pattern 252a of the first dielectric 252 is curved surface like a lens. Referring to FIG. 14, when the top surface of the guide pattern 252a of the first dielectric 252 is a curved surface (or lens), when the voltage is applied to the first electrode 230 and the second electrode 240, the electric field can occur in a direction inclined toward the groove 252c due to the convex shape of the guide pattern 252a like in area B. A plurality of light blocking particles 254b can move into the groove 252c along the electric field direction. Accordingly, when the top surface of the guide pattern 252a is a curved surface (or lens) as in the present disclosure, it is possible to achieve a higher light transmittance in light-transmitting mode compared to the case where the top surface of the guide pattern 252a is a flat surface. In addition, the top surface of the guide pattern 252a is gently inclined, thereby preventing the double image from occurring.

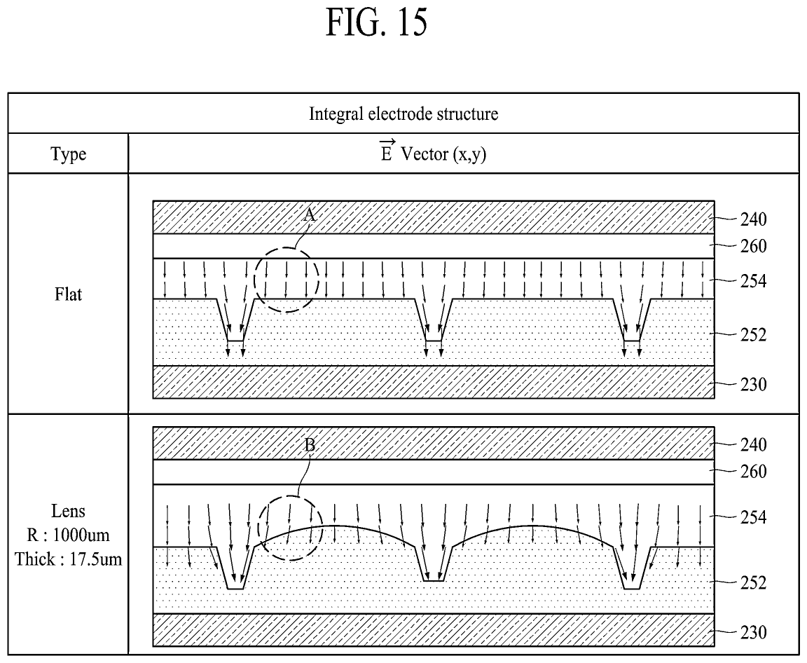

FIG. 15 is a diagram illustrating the difference in electric field direction according to the difference between a dielectric permittivity of the first dielectric and a dielectric permittivity of the second dielectric.

The dielectric permittivity difference between the first dielectric 252 and the solvent 254a of the second dielectric 254 can be less than 15. Referring to FIG. 15, for example, in the case that the dielectric permittivity difference between the first dielectric 252 and the solvent 254a of the second dielectric 254 is 4.4, when the voltage is applied to the first electrode 230 and the second electrode 240, the electric field can be generated in a direction perpendicular to the first electrode 230 like in area A. Since the plurality of light blocking particles 254b move in a direction perpendicular to the first electrode 230 along the electric field direction, the plurality of light blocking particles 254b move into the groove 252c in the area where the groove 252c is formed and some of the plurality of light blocking particles 254b are distributed on the upper surface of the guide pattern 252a.

On the other hand, in the light controlling panel 200 according to the present disclosure, the dielectric permittivity difference between the first dielectric 252 and the solvent 254a of the second dielectric 254 can be equal to or greater than 15. Referring to FIG. 15, for example, in the case that the dielectric permittivity difference between the first dielectric 252 and the solvent 254a of the second dielectric 254 is 33, when the voltage is applied to the first electrode 230 and the second electrode 240, the electric field can be generated in a direction inclined toward the groove 252c due to the convex shape of the guide pattern 252a like in area B. The plurality of light blocking particles 254b can move into the groove 252c along the electric field direction. Accordingly, as in the present disclosure, when the dielectric permittivity difference between the first dielectric 252 and the solvent 254a of the second dielectric 254 is equal to or greater than 15, a high light transmittance can be achieved in the light-transmitting mode compared to the case where the dielectric permittivity difference is small. That is, the greater the difference between the first dielectric permittivity and the second dielectric permittivity, the easier it can be for the light blocking particles 254b to move into the groove 252c of the first dielectric 252 in the light-transmitting mode.

In the present disclosure, since a light-blocking mode and a light-transmitting mode can be implemented using an electrophoretic element, the transparent display device can allow a user to see objects located on rear surface of the transparent display in the light-transmitting mode, and the transparent display device can provide images having a high contrast ratio in the light-blocking mode.

Moreover, in the present disclosure, each of the electrodes provided in the light controlling panel is provided as an integral electrode, thereby reducing the cost of processing the electrode and simplifying a driving circuit.

Moreover, in the present disclosure, since the edge of the electrode is not disposed in the display area of the transparent display panel, it is possible to prevent a plurality of light blocking particles from clumping in the area overlapping the display area of the transparent display panel.

Moreover, in the present disclosure, since the upper surface of the guide pattern of the first dielectric have a convex curved surface, the plurality of light blocking particles move into the groove and do not remain on the upper surface of the guide pattern in the light-transmitting mode, thereby increasing the light transmittance in the light-transmitting mode.

Moreover, in the present disclosure, the guide pattern of the first dielectric can be disposed to overlap with the transmissive area of the transparent display panel, thereby obtaining a high light transmittance when the transparent display device is operated in the light-transmitting mode.

Moreover, in the present disclosure, the groove of the first dielectric can be disposed to overlap with a non-transmissive area of the transparent display panel, thereby preventing the light transmittance of the transparent display device from being reduced due to light blocking particles gathered in the groove of the first dielectric when the transparent display device is operated in the light-transmitting mode.

Moreover, in the present disclosure, since the first dielectric can be formed to have a predetermined thickness in an area where the groove is formed, the impact applied when the light blocking particles gather into the groove can be alleviated, thereby preventing the light blocking particles from being damaged.

Moreover, in the present disclosure, the guide pattern, the spacer, and the groove can be simultaneously formed through an imprinting process, thereby reducing the manufacturing process cost and the manufacturing process time due to the simplicity of the manufacturing process, and further reducing the production energy.

Moreover, in the present disclosure, the manufacturing process for producing the transparent display devices can be reduced and the generation of greenhouse gases due to the manufacturing process can be reduced, thereby improving ESG (Environment/Social/Governance) qualities.

A display device according to one or more example embodiments of the present disclosure may be applied to mobile apparatuses, video phones, smart watches, watch phones, wearable apparatuses, foldable apparatuses, rollable apparatuses, bendable apparatuses, flexible apparatuses, curved apparatuses, variable apparatuses, sliding apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game machines, notebook computers, monitors, cameras, camcorders, home appliances, etc, but embodiments of the present disclosure are not limited thereto.

Moreover, in the present disclosure, a dielectric permittivity difference between the first dielectric and the second dielectric can be large, the plurality of light blocking particles can perfectly move into the groove of the first dielectric.

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A light controlling panel, comprising:
a first electrode and a second electrode disposed to face each other; and
a dielectric layer disposed between the first electrode and the second electrode,
wherein the dielectric layer comprises:
a first dielectric including a first dielectric material and a groove, the first dielectric material having a first dielectric permittivity; and
a second dielectric including a plurality of light blocking particles and a solvent including a second dielectric material having a second dielectric permittivity less than the first dielectric permittivity.

2. The light controlling panel of claim 1, wherein a difference between the first dielectric permittivity and the second dielectric permittivity is equal to or greater than 15.

3. The light controlling panel of claim 2, wherein the first dielectric comprises a guide pattern with a convex top surface, and
wherein the groove is disposed on at least one side of the guide pattern.

4. The light controlling panel of claim 3, wherein the first dielectric further comprises a spacer maintaining a gap between the first electrode and the second electrode.

5. The light controlling panel of claim 4, wherein the groove is disposed between the guide pattern and the spacer.

6. The light controlling panel of claim 4, wherein the groove is disposed between two adjacent guide patterns.

7. The light controlling panel of claim 4, wherein the guide pattern, the groove, and the spacer are formed as single body.

8. The light controlling panel of claim 1, wherein the first dielectric comprises a guide pattern extending in a first direction, and
wherein the groove extends in the first direction parallel to the guide pattern.

9. The light controlling panel of claim 1, wherein the first dielectric is disposed on a top surface of the first electrode, and
wherein the first dielectric has a first thickness in an area where the groove is disposed.

10. The light controlling panel of claim 9, wherein the first dielectric has a second thickness in an area where the guide pattern is disposed, and wherein the first dielectric has a third thickness in an area where the spacer is disposed.

11. The light controlling panel of claim 1, wherein each of the first electrode and the second electrode is a transparent electrode.

12. A transparent display device, comprising:
a display panel including a transmissive area for transmitting an external light and a non-transmissive area on which a plurality of pixels are disposed; and
a light controlling panel including a first electrode, a second electrode, and a dielectric layer disposed between the first electrode and the second electrode,
wherein the dielectric layer comprises:
a first dielectric including a first dielectric material, a guide pattern having a curved top surface, and a groove disposed on at least one side of the guide pattern; and
a second dielectric including a plurality of light blocking particles and a second dielectric material.

13. The transparent display device of claim 12, wherein the guide pattern is disposed in an area corresponding to the transmissive area.

14. The transparent display device of claim 12, wherein the first dielectric is disposed on a top surface of the first electrode, and
wherein the curved top surface of the guide pattern is convex toward the second electrode.

15. The transparent display device of claim 12, wherein the groove is disposed in an area corresponding to the non-transmissive area.

16. The transparent display device of claim 12, wherein the guide pattern extends in a first direction, and
wherein the groove extends in the first direction parallel to the guide pattern.

17. The transparent display device of claim 12, wherein the first dielectric comprises a plurality of guide patterns, and
wherein at least one groove is disposed between two adjacent guide patterns in an area corresponding to the non-transmissive area.

18. The transparent display device of claim 12, wherein the first dielectric has a first thickness in an area where the groove is disposed.

19. The transparent display device of claim 12, wherein the first dielectric further comprises a spacer maintaining a gap between the first electrode and the second electrode.

20. The transparent display device of claim 19, wherein the spacer is disposed in an area corresponding to the non-transmissive area, and
wherein the groove is disposed between the spacer and the guide pattern.

21. The transparent display device of claim 19, wherein the first dielectric comprises a plurality of spacers, and
wherein at least one guide pattern is disposed between two adjacent spacers.

22. The transparent display device of claim 19, wherein the guide pattern, the groove, and the spacer are formed as single body.

23. The transparent display device of claim 19, wherein the first dielectric has a first thickness in an area where the groove is disposed,
wherein the first dielectric has a second thickness in an area where the guide pattern is disposed, and
wherein the first dielectric has a third thickness in an area where the spacer is disposed.

24. The transparent display device of claim 12, wherein the first dielectric has a first dielectric permittivity, and the second dielectric material has a second dielectric permittivity less than the first dielectric permittivity.

25. The transparent display device of claim 12, wherein one transmissive area overlaps one guide pattern.

26. The transparent display device of claim 12, wherein one transmissive area overlaps least two or more guide patterns.

27. The transparent display device of claim 12, wherein the display panel comprises a data line extending in a first direction and a scan line extending in a second direction, and
wherein the guide pattern and the groove extend in the second direction.

28. The transparent display device of claim 12, wherein the light controlling panel is formed of a film type having a flexibility to dispose on one side of the display panel.
